(19) United States
(12) Patent Application Publication
(10) Pub. No.: US 2025/0351604 A1
(43) Pub. Date: Nov. 13, 2025

(54) IMAGE SENSOR

(71) Applicant: SAMSUNG ELECTRONICS CO., LTD., Suwon-si (KR)

(72) Inventors: Daehoon KIM, Suwon-si (KR); Seungjae OH, Suwon-si (KR)

(73) Assignee: SAMSUNG ELECTRONICS CO., LTD., Suwon-si (KR)

(21) Appl. No.: 19/206,630

(22) Filed: May 13, 2025

(30) Foreign Application Priority Data
May 13, 2024 (KR) 10-2024-0062792

(51) Int. Cl. H10F 39/00

(52) U.S. Cl. CPC H10F 39/807; H10F 39/8037; H10F 39/811

(57) ABSTRACT

An image sensor includes a substrate having a first surface and a second surface; a deep element isolation pattern in the substrate to define a plurality of pixel areas; a shallow element isolation pattern adjacent to the first surface to define a first active area, a second active area, and a third active area that are spaced apart in the plurality of pixel areas; a floating diffusion region in the first active area; a control source/drain area in the second active area; a source follower gate on the third active area; and a gate insulating film between the source follower gate and the third active area. The source follower gate and the gate insulating film extend to the control source/drain area. The source follower gate passes through the gate insulating film and is in direct contact with the control source/drain area.

### CROSS-REFERENCE TO RELATED APPLICATION

This application is based on and claims priority under 35 U.S.C. § 119 to Korean Patent Application No. 10-2024-0062792, filed on May 13, 2024, in the Korean Intellectual Property Office, the disclosure of which is incorporated by reference herein in its entirety.

### BACKGROUND

### 1. Field

The disclosure relates to an image sensor.

### 2. Description of Related Art

An image sensor is a semiconductor element that converts an optical image into an electrical signal. Recently, with the development of the computer and communication industries, the demand for image sensors with improved performance has increased in various fields such as digital cameras, camcorders, Personal Communication System (PCS), gaming devices, security cameras, and medical micro cameras. The image sensors can be classified into ‘charge coupled device’ (CCD) type and ‘complementary metal oxide semiconductor’ (CMOS) type. The CMOS type image sensor is provided with a plurality of pixels arranged two-dimensionally. Each of the pixels includes a photodiode (PD). The photodiode serves to convert incident light into an electrical signal.

### SUMMARY

Provided is an image sensor that minimizes parasitic capacitance.

According to an aspect of the disclosure, an image sensor includes: a substrate having a first surface and a second surface opposite to the first surface; a deep element isolation pattern in the substrate to define a plurality of pixel areas; a shallow element isolation pattern adjacent to the first surface to define a first active area, a second active area, and a third active area, wherein the first active area, the second active area, and the third active area are spaced apart in the plurality of pixel areas; a floating diffusion region in the first active area; a control source/drain area in the second active area; a source follower gate on the third active area; and a gate insulating film between the source follower gate and the third active area; wherein the source follower gate and the gate insulating film extend to the control source/drain area, and wherein the source follower gate passes through the gate insulating film and is in direct contact with the control source/drain area.

According to an aspect of the disclosure, an image sensor includes: a substrate having a first surface and a second surface opposite to the first surface; a deep element isolation pattern in the substrate to define a plurality of pixel areas including a plurality of pixel groups; a shallow element isolation pattern adjacent to the first surface to define first active areas, a second active area, and a third active area, wherein the first active areas, the second active area, and the third active area are respectively spaced apart in at least one of the plurality of pixel groups; a photoelectric conversion area in at least one of the plurality of pixel areas; a floating diffusion region in at least one of the first active areas; a control source/drain area in the second active area; a source follower gate on the third active area; a gate insulating film between the source follower gate and the third active area; and a color filter and a microlens sequentially stacked on the second surface of the substrate, wherein the first active areas are respectively provided in at least one of the plurality of pixel areas of the plurality of pixel groups, wherein the source follower gate and the gate insulating film extend on the control source/drain area, and wherein the source follower gate passes through the gate insulating film and is in direct contact with the control source/drain area.

According to an aspect of the disclosure, an image sensor includes: a first substrate having a first surface and a second surface opposite to the first surface; a deep element isolation pattern in the first substrate to define pixel areas; a first shallow element isolation pattern adjacent to the first surface of the first substrate to respectively define first active areas in the pixel areas; a photoelectric conversion area in at least one of the pixel areas; an interlayer insulating film on the first surface of the first substrate; a second substrate disposed on the interlayer insulating film, wherein the second substrate has a third surface facing the first surface of the first substrate and a fourth surface opposite to the third surface; a second shallow element isolation pattern adjacent to the third surface of the second substrate to define a second active area and a third active area; a floating diffusion region respectively in the first active areas; a control source/drain area in the second active area; a source follower gate disposed on the third surface of the second substrate, wherein the source follower gate crosses the third active area; and a gate insulating film disposed between the third active area and the source follower gate, wherein the source follower gate and the gate insulating film extend on the control source/drain area, and wherein the source follower gate passes through the gate insulating film and is in direct contact with the control source/drain area.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram of an image sensor according to one embodiment of the disclosure;

FIG. 2 is a circuit diagram of a pixel array of the image sensor of the disclosure;

FIG. 3 is a circuit diagram of the pixel array of the image sensor according to one embodiment of the disclosure;

FIG. 4 is a plan view of the image sensor according to one embodiment of the disclosure;

FIG. 5 is a cross-sectional view corresponding to line I-I′ of FIG. 4;

FIG. 6 is a cross-sectional view corresponding to line II-II′ of FIG. 4;

FIG. 7 is a cross-sectional view corresponding to line III-III′ of FIG. 4;

FIG. 8 is a cross-sectional view corresponding to line IV-IV′ of FIG. 4;

FIG. 9 is a cross-sectional view of the image sensor according to one embodiment of the disclosure;

FIG. 10 is a plan view of the image sensor according to one embodiment of the disclosure;

FIG. 11 is a plan view of the image sensor according to one embodiment of the disclosure;

FIG. 12 is a plan view of the image sensor according to one embodiment of the disclosure;

FIG. 13 is a plan view of the image sensor according to one embodiment of the disclosure;

FIGS. 14 and 15 are plan views of the image sensors according to one embodiment of the disclosure;

FIG. 16 is a cross-sectional view of the image sensor according to one embodiment of the disclosure;

FIG. 17 is a plan view of the image sensor according to one embodiment of the disclosure;

FIG. 18 is a cross-sectional view of the image sensor according to one embodiment of the disclosure; and

FIGS. 19A to 25C are cross-sectional views and plan views showing a manufacturing method for the image sensor according to one embodiment of the disclosure.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

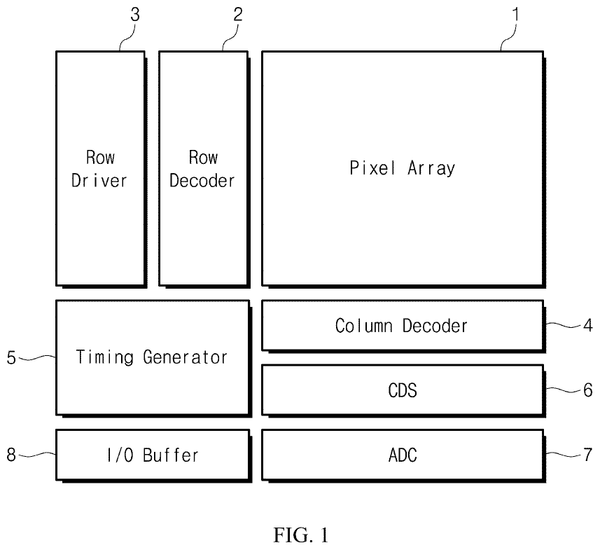

FIG. 1 is a block diagram of an image sensor according to one embodiment of the disclosure. Referring to FIG. 1, the image sensor according to some embodiments of the disclosure may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally. According to one embodiment, some of the pixels may be configured to form a pixel group, and the plurality of pixel groups may be arranged two-dimensionally in the pixel array 1. The pixels may convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the correlated double sampler 6.

The row driver 3 may provide the plurality of driving signals to the pixel array 1 for driving the plurality of pixels based on decoded results from the row decoder 2. When the pixels are arranged in a matrix form, the driving signals may be provided in a row unit.

The timing generator 5 may provide a timing signal and a control signal to the row decoder 2 and the column decoder 4.

The correlated double sampler 6 may receive the electrical signals generated from the pixel array 1 and may hold and sample the received signals. The correlated double sampler 6 may double sample a specific noise level and a signal level caused by an electrical signal to output a difference level corresponding to the difference between the noise level and the signal level.

The analog to digital converter 7 may convert an analog signal corresponding to the difference level output from the correlated double sampler 6 into a digital signal and may output the digital signal.

The input/output buffer 8 may latch the digital signals and sequentially output the latched signals to an image signal processor based on the decoded results from the column decoder 4.

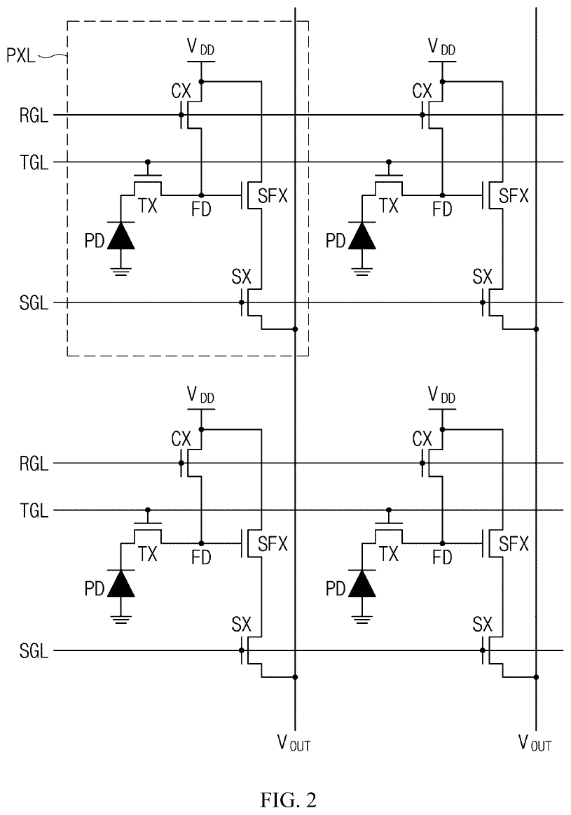

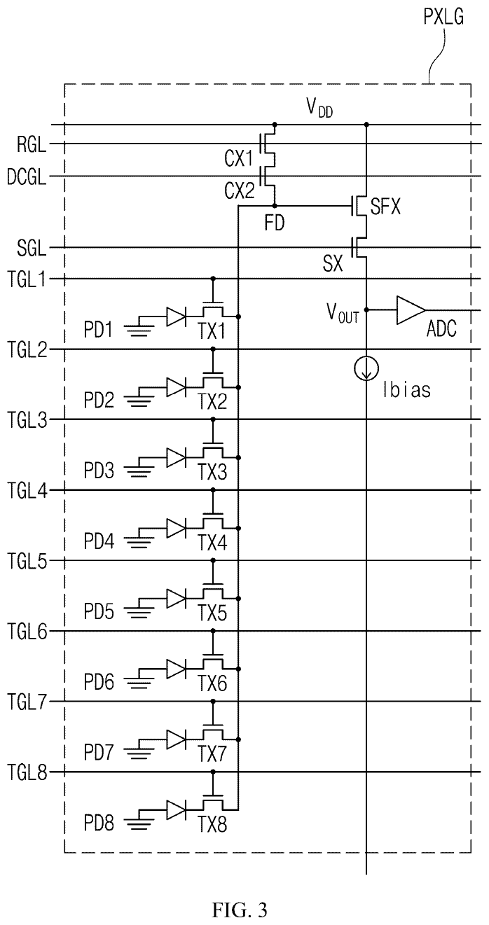

FIG. 2 is a circuit diagram of the pixels included in the pixel array of the image sensor according to one embodiment of the disclosure. FIG. 3 is a circuit diagram of the pixel group included in the pixel array of the image sensor according to one embodiment of the disclosure.

Referring to FIG. 2, the pixel array may include a plurality of pixels PXL, and the pixels PXL may be arranged in a matrix form. Each of (or at least one of) the pixels PXL may include a transfer transistor TX and logic transistors CX, SX, and SFX. The logic transistors CX, SX, and SFX may include a control transistor CX, a selection transistor SX, and a source follower transistor SFX. A transfer gate of the transfer transistor TX may be connected to a transfer gate line TGL. Each of (or at least one of) the pixels PXL may further include a photoelectric conversion element PD and a floating diffusion region FD.

The photoelectric conversion element PD may generate and accumulate photocharges in proportion to amount of light incident from outside. The photoelectric conversion element PD may include a photodiode, a phototransistor, a photogate, a pinned photodiode, or a combination thereof. The transfer transistor TX may transfer the photocharges generated from the photoelectric conversion element PD to the floating diffusion region FD. The floating diffusion region FD may receive and cumulatively store the photocharges generated from the photoelectric conversion element PD.

A gate of the source follower transistor SFX may be connected to the floating diffusion region FD. One source/drain electrode of the source follower transistor SFX may be connected to a power voltage node VDD. The source follower transistor SFX may be controlled according to the amount of photocharges accumulated in the floating diffusion region FD.

The control transistor CX may serve as a reset transistor to periodically reset the charges accumulated in the floating diffusion region FD. A gate of the control transistor CX may be connected to a reset gate line RGL. Source/drain electrodes of the control transistor CX may be connected to the floating diffusion region FD and the power voltage node VDD, respectively. For example, a power source/drain electrode of the control transistor CX may be connected to the power voltage node VDD, and a control source/drain electrode of the control transistor CX may be connected to the floating diffusion region FD. When the control transistor CX is turned on, a power voltage of the power voltage node VDD may be discharged to reset the floating diffusion region FD.

The source follower transistor SFX may serve as a source follower buffer amplifier. The source follower transistor SFX may amplify a potential change in the floating diffusion region FD and output the amplified potential change to an output line VOUT.

A gate of the selection transistor SX may be connected to a selection gate line SGL. Source/drain electrodes of the selection transistor SX may be connected to the other source/drain electrode of the source follower transistor SFX and the output line VOUT, respectively. The selection transistors SX of the pixels PXL to be read in a row unit may be selected by a selection signal applied through a corresponding selection gate line SGL. When the selection transistor SX is turned on, the potential change amplified by the source follower transistor SFX may be output to the output line VOUT through the selection transistor SX.

Referring to FIG. 3, the pixel array may include a plurality of pixel groups PXLG, and each of (or at least one of) the pixel groups PXLG may include photoelectric conversion elements respectively provided to the plurality of pixels and a plurality of transistors.

The plurality of transistors may include the above-described transfer transistor TX, control transistor CX, source follower transistor SFX, and selection transistor SX.

In one embodiment, the transfer transistor TX may be provided in each of (or at least one of) the pixels. For example, the transfer transistors TX of the pixel group PXLG may include first to eighth transfer transistors TX1 to TX8. The photoelectric conversion elements PD1 to PD8 may also be respectively provided in the pixels of the pixel group PXLG.

In one embodiment, the plurality of control transistor CX may be provided in the pixel group PXLG. For example, the control transistors CX may include a first control transistor CX1 and a second control transistor CX2. In this case, the first control transistor CX1 may serve as a reset transistor, and the second control transistor CX2 may serve as a dual conversion gain transistor. A power source/drain electrode of the first control transistor CX1 may be connected to the power voltage node VDD, a control source/drain electrode of the second control transistor CX2 may be connected to the floating diffusion region FD, and the first control transistor CX1 and the second control transistor CX2 may be connected in series between the power voltage node VDD and the floating diffusion region FD. In one embodiment, at least one capacitor or at least one transistor may be connected to a common source/drain electrode between the first control transistor CX1 and the second control transistor CX2.

The pixels of the pixel group PXLG may share the control transistors CX1 and CX2, the floating diffusion region FD, the source follower transistor SFX, and the selection transistor SX.

In one embodiment, the pixel group PXLG including two control transistors CX1 and CX2 is disclosed, but the embodiment of the disclosure is not limited thereto. In one embodiment, the pixel group PXLG may include a larger number of control transistors CX, and a conversion gain mode may be flexibly provided by appropriately turning on and off the disposed control transistors CX. In this case, the control transistors CX may include the plurality of common source/drain electrodes provided between the control transistors.

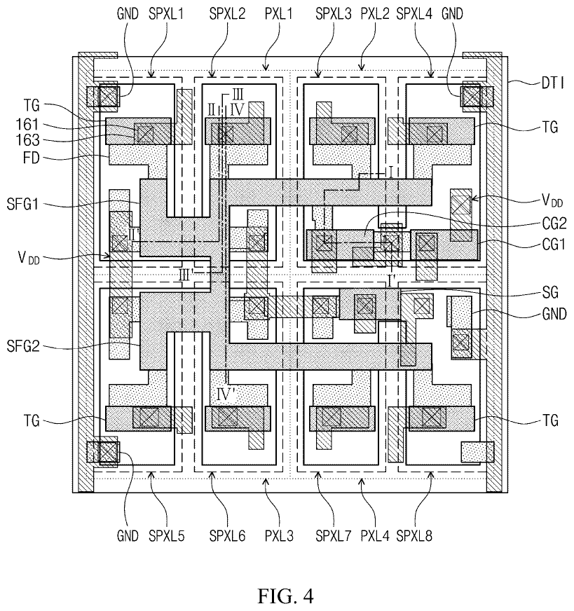

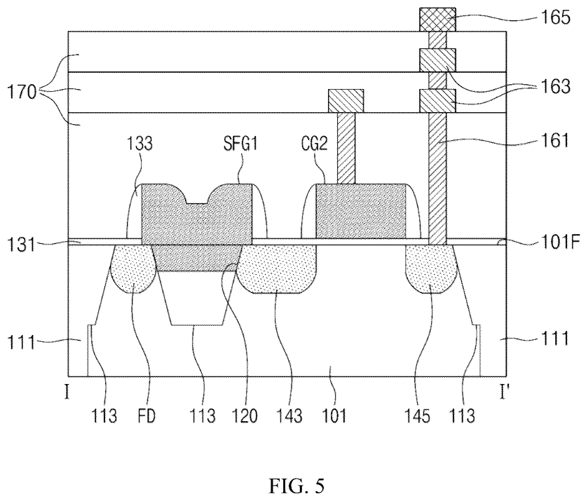

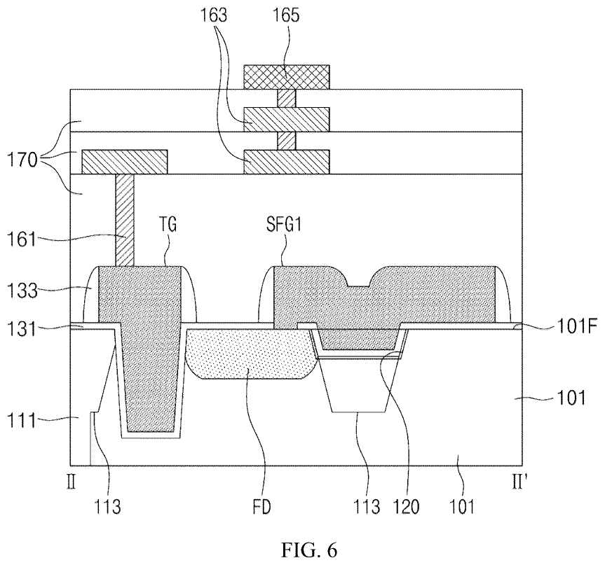

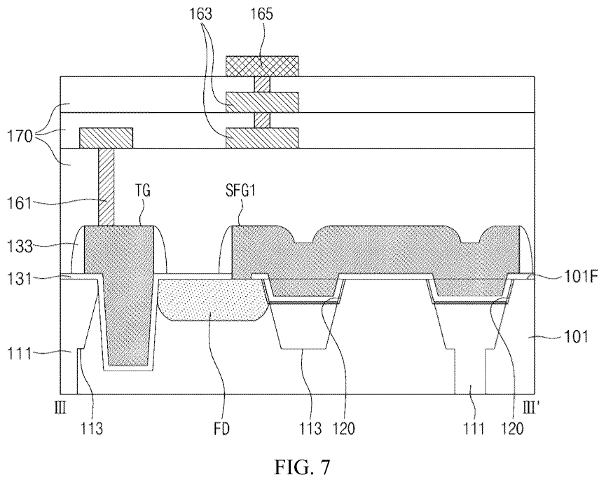

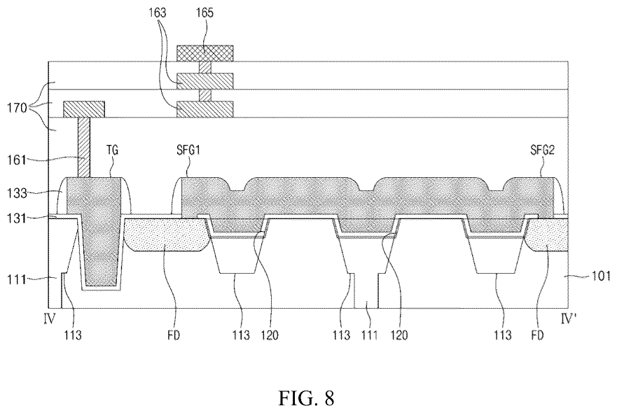

FIG. 4 is a plan view of the image sensor according to one embodiment of the disclosure. FIG. 5 is a cross-sectional view corresponding to line I-I′ of FIG. 4, FIG. 6 is a cross-sectional view corresponding to line II-II′ of FIG. 4, FIG. 7 is a cross-sectional view corresponding to line III-III′ of FIG. 4, and FIG. 8 is a cross-sectional view corresponding to line IV-IV′ of FIG. 4. Hereinafter, overlapping contents with what was described above will be omitted.

In FIGS. 4 to 6, the image sensor may include a substrate 101 and the pixel group PXLG provided on the substrate 101. One pixel group PXLG may be the minimum unit that is repeatedly arranged in a matrix form in the pixel array. In one embodiment, one pixel group PXLG may include the pixels PXL arranged in a 2×2 matrix form. In one embodiment, one pixel group PXLG may include the pixels PXL arranged in a 2×4 matrix form. However, the number of pixels PXL included in one pixel group PXLG is not limited to thereto, and the pixel group PXLG may include various numbers of pixels PXL.

In one embodiment, each of (or at least one of) the pixels PXL may include a pair of sub-pixels SPXL. For example, as shown in FIG. 4, the pixel group PXLG may include first to fourth pixels PXL1 to PXL4 arranged in a 2×2 matrix form, and the first to fourth pixels PXL1 to PXL4 may include first to eighth sub-pixels SPXL1 to SPXL8. However, the embodiments of the disclosure are not limited to thereto.

The pixel group PXLG may include photoelectric conversion areas formed in the substrate 101, transistors provided on the substrate 101, various wirings provided on the substrate 101, and element isolation patterns.

The substrate 101 may be a silicon substrate, a germanium substrate, a silicon-germanium substrate, a group II-VI compound semiconductor substrate, a group III-V compound semiconductor substrate, or a silicon on insulator (SOI) substrate. The substrate 101 may include an impurity of a first conductivity type, and accordingly, the substrate 101 may have the first conductivity type. For example, the impurity of the first conductivity type may be a group III element. For example, the impurity of the first conductivity type may include a p-type impurity such as aluminum (Al), boron (B), indium (In), and/or gallium (Ga).

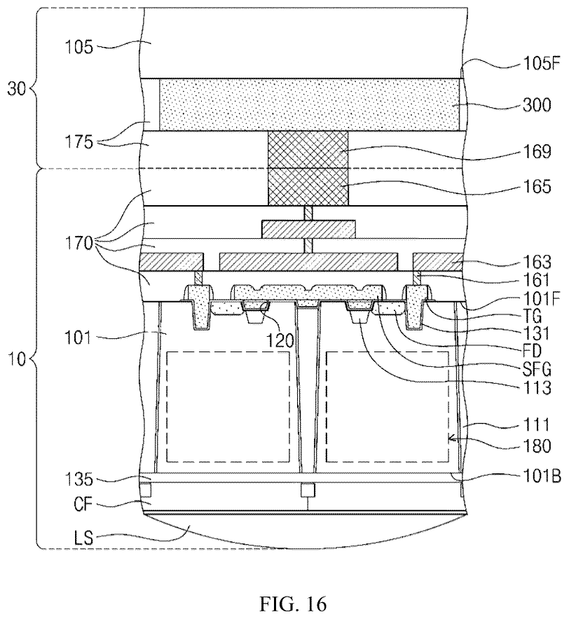

The photoelectric conversion areas (see 180 in FIG. 16) may include an impurity of a second conductivity type different from the first conductivity type, and accordingly, the photoelectric conversion areas may have the second conductivity type. For example, the second conductivity type may be a group V element. For example, the impurity of the second conductivity type may include a n-type impurity such as phosphorus, arsenic, bismuth, and/or antimony.

The substrate 101 and the photoelectric conversion areas may be P—N junctioned to form the photoelectric conversion elements PD described above. The substrate 101 may have a first surface 101F and a second surface opposite to the first surface 101F. The first surface 101F may be a front surface of the substrate, and the second surface may be a back surface of the substrate. Light may be incident on the second surface of the substrate 101.

A deep element isolation pattern 111 may pass through the substrate 101 to define the plurality of pixel areas, and a shallow element isolation pattern 113 may be formed adjacent to the first surface 101F of the substrate to define a plurality of active areas in the plurality of pixel areas.

The deep element isolation pattern 111 may be formed in the substrate 101 to surround each of (or at least one of) the pixel areas when viewed from a plan view. For example, the deep element isolation pattern 111 may be formed by a technology (i.e., a deep trench isolation (DTI) technology) that fills a deep trench formed by patterning the substrate 101 with an insulating material. The pixel area surrounded by the deep element isolation pattern 111 may be a portion of the substrate 101.

The deep element isolation pattern 111 may be provided in a form passing through the substrate 101. For example, the deep element isolation pattern 111 may pass through the first and second surfaces of the substrate 101 and a substrate body between the first and second surfaces of the substrate 101.

In one embodiment, each of (or at least one of) the pixel areas may be defined in each of (or at least one of) the pixels PXL. The photoelectric conversion areas may be respectively disposed in the pixel areas. In one embodiment, when each of (or at least one of) the pixels PXL includes a pair of sub-pixels SPXL, each of (or at least one of) the pixel areas may include a pair of sub-pixel areas. The pair of sub-pixel areas may be separated by at least one of various isolation technologies. For example, the pair of sub-pixel areas may be separated by a doping isolation technique. That is, a doped isolation area may be provided between the pair of sub-pixel areas. In one embodiment, the pair of sub-pixel areas may be separated each other by the doped isolation area and the deep element isolation pattern 111. That is, the doped isolation area and the deep element isolation pattern 111 may be provided between the pair of sub-pixel areas. In one embodiment, only the deep element isolation pattern 111 may be provided between the pair of sub-pixel areas. When each of (or at least one of) the pixel areas includes the pair of sub-pixel areas, the photoelectric conversion areas may be respectively disposed in the sub-pixel areas.

In one embodiment, the deep element isolation pattern 111 may include a conductive isolation film provided in the deep trench and an insulating liner provided between the substrate 101 and the conductive isolation film. The conductive isolation film may include a conductive material such as a doped semiconductor material (e.g., doped polysilicon). The conductive isolation film may be spaced apart from the substrate 101 by the insulating liner, and accordingly, during the operation of the image sensor, the conductive isolation film may be electrically isolated from the substrate 101.

The shallow element isolation pattern 113 may be disposed in a shallow trench recessed by a predetermined depth from the first surface 101F. For example, the shallow element isolation pattern 113 may be formed by a technology (i.e., a shallow trench isolation (STI) that fills the shallow trench with an insulating material technology) and may not pass through the substrate 101. The shallow element isolation pattern 113 may include at least one of a silicon oxide, a silicon nitride, a silicon oxynitride, or a combination thereof, but is not limited thereto.

In one embodiment, the shallow element isolation pattern 113 may define active areas spaced apart from each other in the pixel areas. For example, the shallow element isolation pattern 113 may be provided between the active areas to electrically isolate the active areas from each other. Specifically, the shallow element isolation pattern 113 may electrically isolate a first active area and a second active area, a first active area and a third active area, a first active area and a fourth active area, a first active area and a fifth active area, a second active area and a fifth active area, a third active area and a fifth active area, and a fourth active area and a fifth active area.

In one embodiment, the deep element isolation pattern 111 may partially overlap the shallow element isolation pattern 113. An overlapping portion of the deep element isolation pattern 111 and the shallow element isolation pattern 113 may correspond to one portion of the shallow element isolation pattern 113 or one portion of the deep element isolation pattern 111. Hereinafter, for convenience of explanation, the overlapping portion of the deep element isolation pattern 111 and shallow element isolation pattern 113 will be described as one portion of the shallow element isolation pattern 113. In one embodiment, the shallow element isolation pattern 113 may include a recessed area 120 defined by partially recessing the shallow element isolation pattern 113.

Gates TG, SFG1, SFG2, CG1, CG2, and SG may be disposed on the first surface 101F of the substrate 101. An interlayer insulating film 170 may be disposed on the first surface 101F of the substrate 101 to cover the gates. Wirings 163 may be disposed on the interlayer insulating film 170. Each of (or at least one of) the wirings 163 may be electrically connected to a corresponding gate or an impurity area (e.g., a source/drain area or a ground area) through a contact plug 161 passing through the interlayer insulating film 170.

Each of (or at least one of) the active areas may be a part of the substrate 101 surrounded by the shallow element isolation pattern 113 from a planar perspective. The active area may be defined from the first surface 101F of the substrate 101 to a predetermined depth. Each of (or at least one of) the gates may be disposed on a corresponding active area. In one embodiment, a source/drain area, a floating diffusion region, and a ground area GND may be formed in the active areas. For example, the plurality of floating diffusion regions FD, source/drain areas of the source follower transistor, source/drain areas (control source/drain area 143 and common source/drain area 145) of the control transistor, source/drain areas of the selection transistor, and the ground areas GND may be provided in the active areas.

In one embodiment, the plurality of pixel areas may include the first to fifth active areas spaced apart from each other. The floating diffusion region FD may be disposed in the first active area, and a control source/drain area and a power source/drain area may be disposed in the second active area. The control source/drain area and the power source/drain area may correspond to the control source/drain electrode and the power source/drain electrode described with reference to FIGS. 2 and 3, respectively. The third active area and the fourth active area may include source/drain areas respectively disposed in the third active area and the fourth active area and the fifth active area may include the ground area GND. In one embodiment, when the plurality of control transistors are provided, the second active area may further include at least one common source/drain area disposed in the second active area. The common source/drain area may correspond to the common source/drain electrode described with reference to FIGS. 3 and 4.

The gates TG, SFG1, SFG2, CG1, CG2, and SG may include a conductive material (e.g., doped polysilicon). In one embodiment, the gates TG, SFG1, SFG2, CG1, CG2, and SG may further include a metal-containing material (e.g., metal silicide) disposed on the doped polysilicon.

A gate insulating film 131 may be disposed between the active areas and the gates TG, SFG1, SFG2, CG1, CG2, and SG, and a gate spacer 133 may be provided on each of (or at least one of) side surfaces of the gates TG, SFG1, SFG2, CG1, CG2, and SG. In one embodiment, when at least one of the gates TG, SFG1, SFG2, CG1, CG2, and SG extends onto another active area, the gate insulating film 131 may extend along at least one of the gates.

The transfer gate TG may be disposed on the first active area of one side of the floating diffusion region FD. In one embodiment, the transfer gate TG may fill a gate trench formed in the first active area of one side of the floating diffusion region FD. In this case, the gate insulating film 131 may also be disposed between the transfer gate TG and an inner surface of the gate trench. When the transfer gate TG fills the gate trench, the transfer transistor may be a vertical channel type transistor. In one embodiment, the transfer gate TG may be provided as one electrode in each pixel or each sub-pixel, but is not limited thereto. In one embodiment, the transfer gate TG may be provided as a pair of electrodes spaced apart from each other in each pixel or each sub-pixel.

The plurality of first active area may be provided. The first active areas may be respectively defined in the pixel areas. When each of (or at least one of) the pixel areas includes the pair of sub-pixel areas, the first active areas may be respectively defined in the sub-pixel areas.

The first control gate CG1 may be disposed on the second active area of one side of the power source/drain area, and the power voltage node V_{DD} may be connected to the power source/drain area. The first control gate CG1 may correspond to a reset gate.

The second control gate CG2 may be disposed on the second active area of one side of the control source/drain area 143. The second control gate CG2 may correspond to a dual conversion gain gate.

The common source/drain area 145 may be disposed in the second active area between the first control gate CG1 and the second control gate CG2. At least one capacitor or at least one transistor may be electrically connected to the common source/drain area 145.

The source follower gates SFG1 and SFG2 may be disposed on the third active area and may extend on at least one of the first active area, the second active area, and the shallow element isolation pattern 113.

For example, the source follower gates SFG1 and SFG2 may extend on at least one of the floating diffusion region FD in the first active area, the control source/drain area 143 in the second active area, and the shallow element isolation pattern 113.

When the source follower gates SFG1 and SFG2 extend on the shallow element isolation pattern 113, the source follower gates SFG1 and SFG2 may fill the recessed area 120 defined in the shallow element isolation pattern 113.

For example, the source follower gates SFG1 and SFG2 may fill the recessed area 120 defined in the shallow element isolation pattern 113 between the control source/drain area 143 and the floating diffusion region FD, and may fill the recessed area defined in the shallow element isolation pattern 113 between the floating diffusion region FD and the second active area and/or between the floating diffusion region FD and the third active area.

In one embodiment, the pixel areas of the pixel group may include the plurality of third active areas spaced apart from each other, and the source follower gates SFG1 and SFG2 may include first and second source follower gates SFG1 and SFG2 respectively disposed on the third active areas. In this case, the first and second source follower gates SFG1 and SFG2 may extend to be directly connected to each other. That is, the first and second source follower gates SFG1 and SFG2 may form a single body without an interface therebetween. In this case, the first and second source follower gates SFG1 and SFG2 integrally connected may fill the recessed area 120 defined in the shallow element isolation pattern 113 between the third active areas.

In one embodiment, the gate insulating film 131 may extend between the extended portion of the source follower gates SFG1 and SFG2 and the substrate 101.

For example, the gate insulating film 131 may extend on at least one of the first active area, the second active area, and the shallow element isolation pattern 113 along the source follower gates SFG1 and SFG2. For example, the gate insulating film 131 may extend on the floating diffusion region FD in the first active area, the control source/drain area 143 in the second active area, and the shallow element isolation pattern 113 along the source follower gates SFG1 and SFG2.

In one embodiment, the source follower gates SFG1 and SFG2 may pass through the gate insulating film 131 to be in direct contact with the active areas. According to one embodiment, the source follower gates SFG1 and SFG2 may pass through the gate insulating film 131 to be in direct contact with the control source/drain area 143 in the second active area. In addition, the source follower gates SFG1 and SFG2 may pass through the gate insulating film 131 to be in direct contact with the floating diffusion region FD in the first active area.

The selection gate SG may be disposed on the fourth active area, and the source/drain areas may be disposed in the fourth active area at both sides of the selection gate SG. The source/drain areas of the fourth active area may correspond to source/drain electrodes of the selection transistor and may be respectively connected to the other source/drain electrode of the source follower transistor in FIG. 3 or 4 and the output line VOUT.

As described above, the interlayer insulating film 170 may be disposed on the first surface 101F of the substrate 101, and the wirings 163 may be disposed on the interlayer insulating film 170. The wirings 163 as shown may form a multi-layered structure. In this case, the plurality of interlayer insulating films 170 may be sequentially stacked on the first surface 101F of the substrate 101. In one embodiment, the wirings may form a single-layered structure. In one embodiment, bonding pads 165 may be disposed on the uppermost interlayer insulating film 170. The bonding pads 165 may be electrically connected to the corresponding wirings 163 through some contact plugs 161.

The wirings 163 may include the gate lines TGL, RGL, and SGL (see FIG. 3 or FIG. 4), the power voltage line VDD, the output line VOUT (see FIG. 3 or FIG. 4), a battery voltage line, a local connection line, and the like. The wirings 163 may be connected to corresponding source/drain areas and corresponding gates through the contact plugs 161, thereby implementing the pixel PXL of FIG. 3 or the pixel group PXLG of FIG. 4. In one embodiment, the wirings 163 and the contact plugs 161 may not be connected to the source follower gates SFG1 and SFG2.

For example, the selection gate SG may be connected to the corresponding wiring 163 through the contact plug 161 provided on the selection gate SG. The transfer gate TG may be connected to the corresponding wiring 163 through the contact plug 161 provided on the transfer gate TG. The first control gate CG1 may be connected to the corresponding wiring 163 through the contact plug 161 provided on the first control gate CG1. The second control gate CG2 may be connected to the corresponding wiring 163 through the contact plug 161 provided on the second control gate CG2. The ground area GND may be connected to the corresponding wiring 163 through the contact plug 161 provided on the ground area GND.

In addition, one source/drain area of the source follower transistor disposed on the third active area may be electrically connected to one source/drain area of the selection transistor disposed on the fourth active area through the corresponding contact plugs 161 and the corresponding wiring 163. The other source/drain area of the selection transistor may be electrically connected to the corresponding wiring 163 (e.g., the output line VOUT) through the corresponding contact plug 161. The common source/drain area between the first control gate CG1 and the second control gate CG2 may be connected to at least one capacitor or at least one transistor through the contact plug 161 and the corresponding wiring 163. The other source/drain area of the source follower transistor and the power source/drain area of the first control transistor may be connected to the corresponding wiring 163 through the corresponding contact plugs 161, and the power voltage may be applied through the corresponding wiring 163.

Referring to FIGS. 4 and 5, the floating diffusion region FD and the control source/drain area 143 may be connected through the source follower gates SFG1 and SFG2 extended from the third active area onto the shallow element isolation pattern 113. The recessed area 120 defined by recessing the shallow element isolation pattern 113 may be filled with the source follower gates SFG1 and SFG2.

In one embodiment, the gate insulating film 131 may be included between the source follower gates SFG1 and SFG2 and the control source/drain area 143, and the source follower gates SFG1 and SFG2 may pass through the gate insulating film 131 to be in direct contact with the control source/drain area 143. In addition, the gate insulating film 131 may be included between the source follower gates SFG1 and SFG2 and the floating diffusion region FD, and the source follower gates SFG1 and SFG2 may pass through the gate insulating film 131 to be in direct contact with the floating diffusion region FD. In addition, the gate insulating film 131 may be included even between the source follower gates SFG1 and SFG2 and the shallow element isolation pattern 113.

In one embodiment, the recessed area 120 may expose one side surface of the floating diffusion region FD and/or one side surface of the control source/drain area 143, and the source follower gates SFG1 and SFG2 filling the recessed area 120 may be in contact with the exposed side surface of the floating diffusion region FD and the exposed side surface of the control source/drain area 143. That is, the gate insulating film 131 between the source follower gates SFG1 and SFG2 and the floating diffusion region FD may be removed, and the gate insulating film 131 between the source follower gates SFG1 and SFG2 and the control source/drain area 143 may be removed. In addition, the gate insulating film 131 between the source follower gates SFG1 and SFG2 and the shallow element isolation pattern 113 may also be removed.

Referring to FIGS. 4, 6, and 7, the source follower gate SFG1 may extend from the third active area to the first active area to be connected to the floating diffusion region FD. The source follower gate SFG1 may be also disposed on the shallow element isolation pattern 113 between the third active area and the first active area, and the source follower gates SFG1 and SFG2 may fill the recessed area 120 defined by recessing the shallow element isolation pattern 113.

In one embodiment, the gate insulating film 131 may be disposed between the source follower gate SFG1 and the third active area, and the source follower gate SFG1 may pass through the gate insulating film 131 to be directly connected to the floating diffusion region FD. The portion where the source follower gate SFG1 passes through the gate insulating film 131 is not limited thereto. In one embodiment, the source follower gate SFG1 may pass through the gate insulating film 131 excluding the recessed area 120 to be directly connected to the floating diffusion region FD.

Referring to FIGS. 4 and 8, a first source follower gate SFG1 of a first pixel PXL1 may extend from the third active area of the first pixel PXL1 to the first active area of the first pixel PXL1 to be in contact with the floating diffusion region FD of the first pixel PXL1. The first source follower gate SFG1 of the first pixel PXL1 may be also disposed on the shallow element isolation pattern 113 between the third active area and the first active area in the first pixel PXL1, and the first source follower gate SFG1 may fill the recessed area 120 defined by recessing the shallow element isolation pattern 113.

In addition, a second source follower gate SFG2 of a third pixel PXL3 may extend from the third active area of the third pixel PXL3 to the first active area of the third pixel PXL3 to be in contact with the floating diffusion region FD of the third pixel PXL3. The second source follower gate SFG2 of the third pixel PXL3 may be also disposed on the shallow element isolation pattern 113 between the third active area and the first active area in the third pixel PXL3, and the second source follower gate SFG2 may fill the recessed area 120 defined by recessing the shallow element isolation pattern 113.

In addition, the first source follower gate SFG1 of the first pixel PXL1 and the second source follower gate SFG2 of the third pixel PXL3 may extend to be connected to each other on the deep element isolation pattern 111 between the first and third pixels PXL1 and PXL3. As described above, the first and second source follower gates SFG1 and SFG2 may form a single body without an interface therebetween. The first and second source follower gates SFG1 and SFG2 integrally formed may fill the recessed area 120 defined by recessing the shallow element isolation pattern 113 between the first and third pixels PXL1 and PXL3. That is, the first source follower gate SFG1 of the first pixel PXL1 and the second source follower gate SFG2 of the third pixel PXL3 may form one source follower gate in the pixel group PXLG.

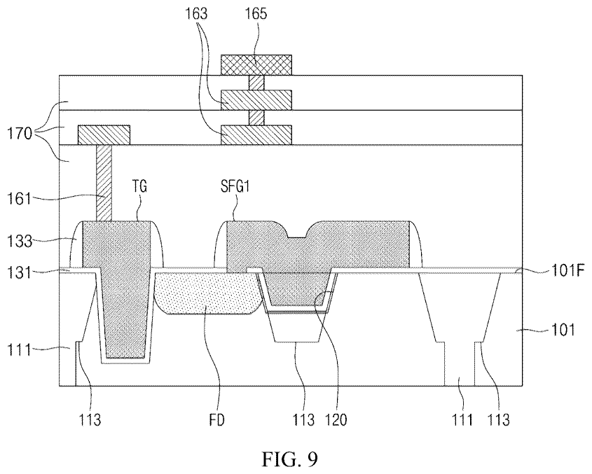

FIG. 9 is a cross-sectional view of the image sensor including the shallow element isolation pattern with the recessed area extended according to one embodiment of the disclosure.

Referring to FIGS. 6 and 9, a size of the recessed area 120 defined by recessing the shallow element isolation pattern 113 may vary depending on the degree recessing the shallow element isolation pattern 113.

The recessed area 120 of FIG. 9 may be deeper than the recessed area 120 of FIGS. 5 to 8. In this case, a side surface of the third active region covered by the source follower gate SFG1 in the recess area 120 of FIG. 9 may be wider. Accordingly, a width of a channel area defined in the third active area in FIG. 9 may be greater than a width of a channel area defined in the third active area in FIG. 6. As a result, the width of the channel area of the source follower transistor including the source follower gate SFG1 may be adjusted by controlling a depth of the recessed area 120.

In the above-described embodiments, the source follower gate may be in direct contact with the control source/drain area 143 used as one source/drain area of the first control transistor (e.g., a reset transistor) or one source/drain area of the second control transistor (e.g., a dual conversion gain transistor). Accordingly, the contact plugs and the wiring for connecting the source follower gate and the control source/drain area 143 may be omitted. In addition, the source follower gate may be in direct contact with the floating diffusion regions FD. Accordingly, the contact plugs and the wiring for connecting the source follower gate and the floating diffusion region FD may be omitted.

Accordingly, the parasitic capacitance between the source follower gate and the control source/drain area can be minimized, and the parasitic capacitance between the source follower gate and the floating diffusion region FD can also be minimized. As a result, the capacitance of a floating node composed of the control source/drain area, the source follower gate, and the floating diffusion region, which are electrically connected, can be minimized, thereby improving a conversion gain of the pixels.

Furthermore, the source follower gate may fill the recessed area of the shallow element isolation pattern. Accordingly, the width of the channel area of the source follower transistor can be increased, thereby improving the performance of the source follower transistor. The image sensor according to one embodiment of the present disclosure may be modified in various forms.

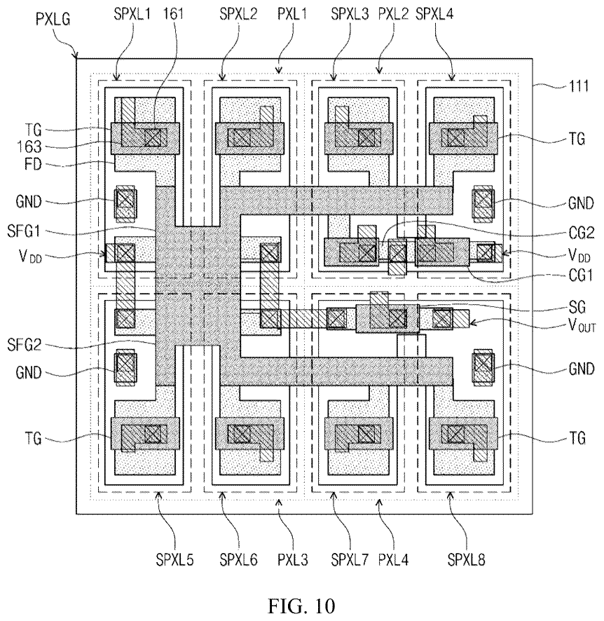

FIG. 10 is a plan view of the image sensor according to one embodiment of the disclosure. Referring to FIGS. 4 and 10, unlike the first active area of FIG. 4 disposed on one side of the transfer gate TG, the first active area of FIG. 10 may be further extended to be disposed on both sides of the transfer gate TG. As the first active area of FIG. 10 is extended, the second to fourth active areas of FIG. 10 may be smaller than the second to fourth active areas of FIG. 4, and the fifth active area of FIG. 10 may be disposed in a different location from the fifth active area of FIG. 4.

As disclosed above, the first source follower gate SFG1 of the first pixel PXL1 and the second source follower gate SFG2 of the third pixel PXL3 may extend to be integrally connected on the deep element isolation pattern 111 between the first and third pixels PXL1 and PXL3. The integrally formed first and second source follower gates (SFG1, SFG2) may fill the recessed area 120 formed at a boundary between the first and third pixels PXL1 and PXL3.

The integrated source follower gate of FIG. 4 may cross the deep element isolation pattern and the shallow element isolation pattern between the second sub-pixel SPXL2 and the sixth sub-pixel SPXL6, while the integrated source follower gate of FIG. 10 may cross the deep element isolation pattern and the shallow element isolation pattern between the first and second sub-pixels SPXL1 and SPXL2 and the fifth and sixth sub-pixels SPXL5 and SPXL6.

Accordingly, the shallow element isolation pattern of FIG. 4 may include the recessed area between the second and sixth sub-pixels SPXL2 and SPXL6, while the shallow element isolation pattern of FIG. 10 may include the recessed area between the first and fifth sub-pixels SPXL1 and SPXL5 and between the second and sixth sub-pixels SPXL2 and SPXL6.

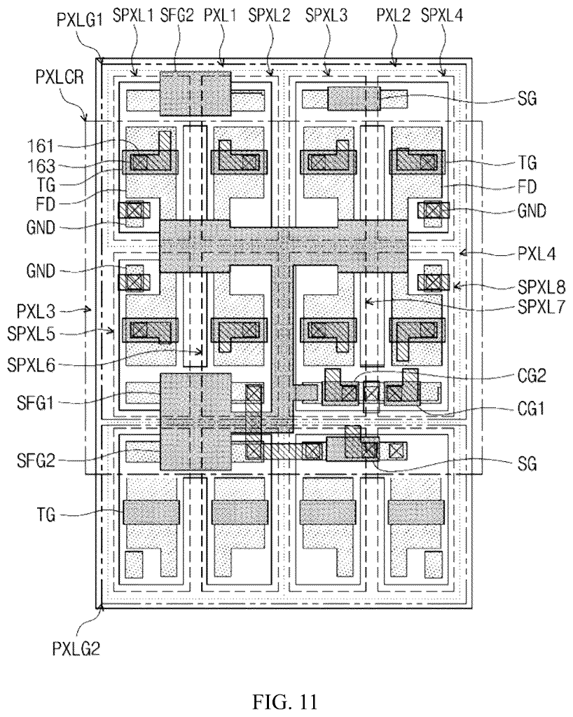

FIG. 11 is a plan view of the image sensor according to one embodiment of the disclosure. Referring to FIGS. 10 and 11, the pixel group PXLG1 of FIG. 11 may be composed of the first to fourth pixels PXL1 to PXL4 like the pixel groups PXLG of FIGS. 4 and 10 disclosed above. However, in the pixel group PXLG1 of FIG. 11, a pixel circuit area PXLCR may be disposed to be shifted from the pixel areas including the photoelectric conversion areas.

For example, the first pixel group PXLG1 of FIG. 11 may include all of two third active areas, two source follower gates SFG1 and SFG2, two fourth active areas, and a select gate SG, but the pixel circuit area PXLCR may include one third active area and one source follower gate SFG1 of the first pixel group PXLG1, and one third active area, one source follower gate SFG2, one fourth active area, and one select gate SG of the second pixel group PXLG2. That is, the pixel circuit area PXLCR of FIG. 11 may be configured to transmit the electrical signal transmitted from the transfer transistors of the first pixel group PXLG1 to the select transistor of the second pixel group PXLG2 via the source follower transistors of the first and second pixel groups PXLG1 and PXLG2.

Somewhat similar to the source follower gates SFG1 and SFG2 of FIG. 10 according to one embodiment of the disclosure, the source follower gates SFG1 and SFG2 of FIG. 11 may cross the deep element isolation pattern between the sub-pixels SPXL. For example, the source follower gates SFG1 and SFG2 of FIG. 11 may cross the deep element isolation pattern and the shallow element isolation pattern between the fifth and sixth sub-pixels SPXL5 and SPXL6 in the first pixel group PXLG1 and the first and second sub-pixels SPXL1 and SPXL2 in the second pixel group PXLG2.

Accordingly, the shallow element isolation pattern of FIG. 11 may include the recessed area between the fifth and sixth sub-pixels SPXL5 and SPXL6 in the first pixel group PXLG1 and the first and second sub-pixels SPXL1 and SPXL2 in the second pixel group PXLG2.

In addition, for example, as the third active area and the fourth active area may be disposed outside the first pixel group PXLG1 and the first active area may be disposed inside the first pixel group PXLG1, the source follower gates SFG1 and SFG2 of FIG. 11 may extend along the deep element isolation pattern in the third active area, and the floating diffusion regions FD may be disposed on both sides thereof. In one embodiment, the shallow element isolation pattern on at least one side of which is in contact with the floating diffusion region FD may include the recessed area, and the remaining shallow element isolation pattern may selectively include the recessed area.

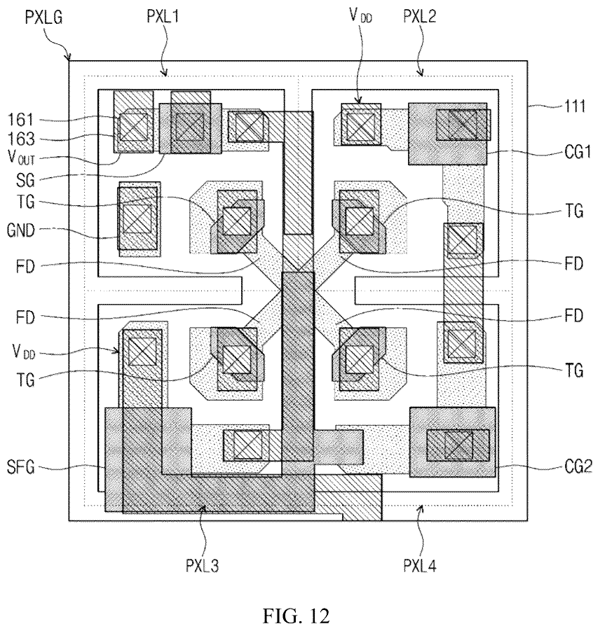

FIG. 12 is a plan view of the image sensor including four photodiodes according to one embodiment of the disclosure. Referring to FIG. 12, the pixel group PXLG of FIG. 12 may be composed of four pixels PXL1 to PXL4 and may include four transfer gates TG. Unlike the pixel group PXLG of FIGS. 4, 10, and 11, which includes eight transfer gates TG in a single pixel group PXLG including two sub-pixels SPXL, the pixel group PXLG of FIG. 12 may be composed of four pixels PXL1 to PXL4, each of (or at least one of) which includes one transfer gate TG.

The first pixel PXL1 of FIG. 12 may include the transfer gate TG, the select gate SG, and the ground area GND including the first active area, the fourth active area, and the fifth active area, the second pixel PXL2 may include the transfer gate TG and a first control gate CG1 including the first active area and the second active area, the third pixel PXL3 may include the transfer gate TG and the source follower gate SFG including the first active area and the third active area, and the fourth pixel PXL4 may include the transfer gate TG and a second control gate CG2 including the first active area and the second active area.

In addition, the first active area of FIG. 12 may be disposed to connect to the source follower gate SFG extending to a center portion of the pixel group PXLG when viewed from a plan view. In one embodiment, the first active areas of the pixels PXL1 to PXL4 may be in direct contact with each other at the center portion of the pixel group PXLG to form a single body, or may be spaced apart from each other while extending to the center portion of the pixel group PXLG.

In one embodiment, when the first active areas in the pixel group PXLG of FIG. 12 are spaced apart from each other, the shallow element isolation pattern may be formed below the source follower gate SFG of FIG. 12. The shallow element isolation pattern may include the recessed area, and the recessed area may be provided with the source follower gate SFG and the gate insulating film, and the source follower gate SFG may pass through the gate insulating film to be in direct contact with the floating diffusion regions FD of the plurality of first active areas.

One transfer gate TG may be provided on each of (or at least one of) the first active areas, but is not limited thereto. In one embodiment, the transfer gate TG of the first active areas may include a pair of electrodes spaced apart from each other.

Unlike the above-described embodiments, in FIG. 12, the plurality of second active areas may be respectively disposed in different pixels PXL. For example, the second active areas of FIG. 12 may include the second active area provided in the second pixel PXL2 and the second active area provided in the fourth pixel PXL4. In this case, the common source/drain area between the first and second control gates CG1 and CG2 may also be divided into two common source/drain areas. The common source/drain areas spaced apart from each other may be electrically connected through the corresponding contact plugs 161 and the corresponding wiring 163.

The second active area of the fourth pixel PXL4 according to one embodiment may be in direct contact with the source follower gate SFG extending along the deep element isolation pattern from the third active area. For example, the shallow element isolation pattern overlapped on the deep element isolation pattern of the pixel group PXLG may be in contact with the second active area of the fourth pixel PXL4, and the shallow element isolation pattern may include the recessed area defined by recessing a side of the shallow element isolation pattern being in contact with the second active area. In this case, the source follower gate SFG extending along the deep element isolation pattern may fill the recessed area. That is, the source follower gate SFG may cover the shallow element isolation pattern exposed by the recess.

In one embodiment, the gate insulating film may be provided between the source follower gate SFG and the shallow element isolation pattern and between the source follower gate SFG and the second active area, and the source follower gate SFG may pass through the gate insulating film to be in direct contact with the control source/drain area in the second active area.

In one embodiment, the gate insulating film may be removed between the source follower gate SFG and the shallow element isolation pattern and between the source follower gate SFG and the second active area, and the source follower gate SFG may be in direct contact with the control source/drain area in the shallow element isolation pattern and the second active area.

The source follower gate SFG disposed on the third active area as described above may extend along the deep element isolation pattern from the third active area and may be in contact with the first active area and the second active area. When the source follower gate SFG is disposed above the deep element isolation pattern, the shallow element isolation pattern overlapped on the deep element isolation pattern corresponding to a location of the source follower gate SFG may be recessed to include the recessed area. That is, the shallow element isolation pattern overlapped on the deep element isolation pattern may include the recessed area in an area corresponding to the source follower gate SFG and the deep element isolation pattern when viewed from a plan view, and the source follower gate SFG disposed in the corresponding area may fill the recessed area.

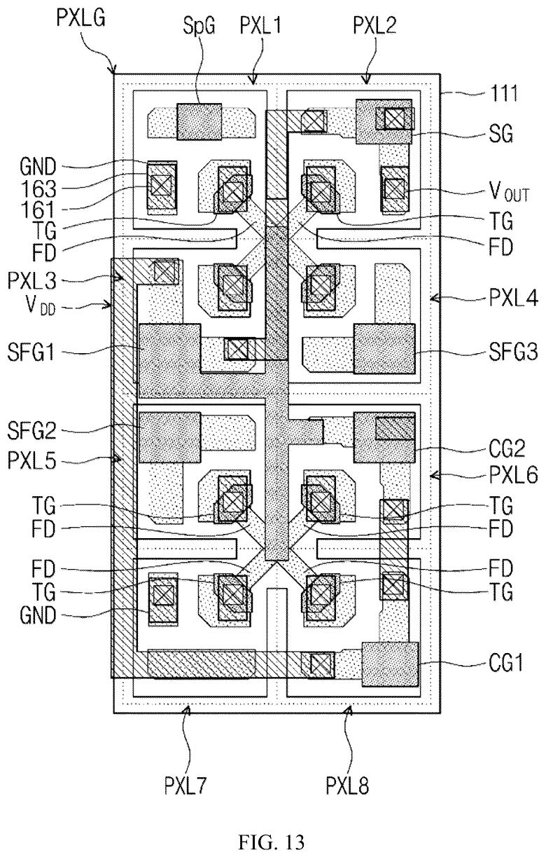

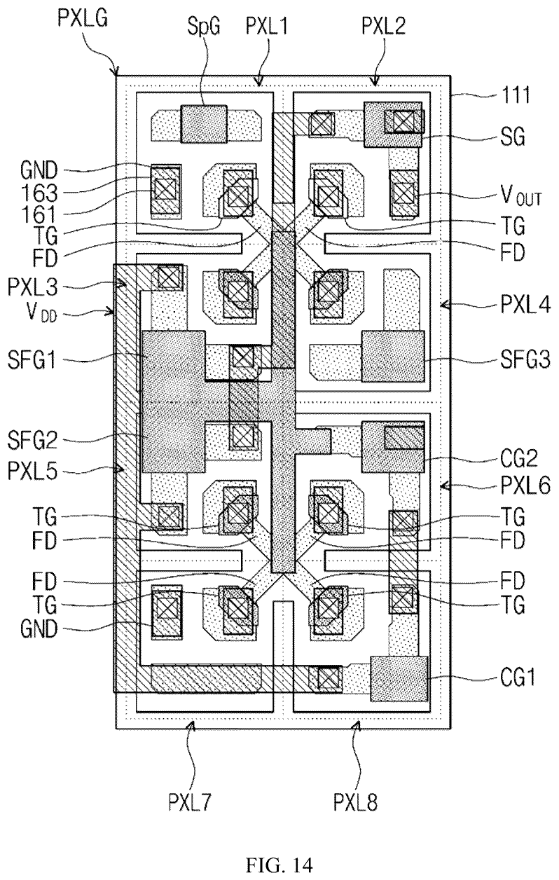

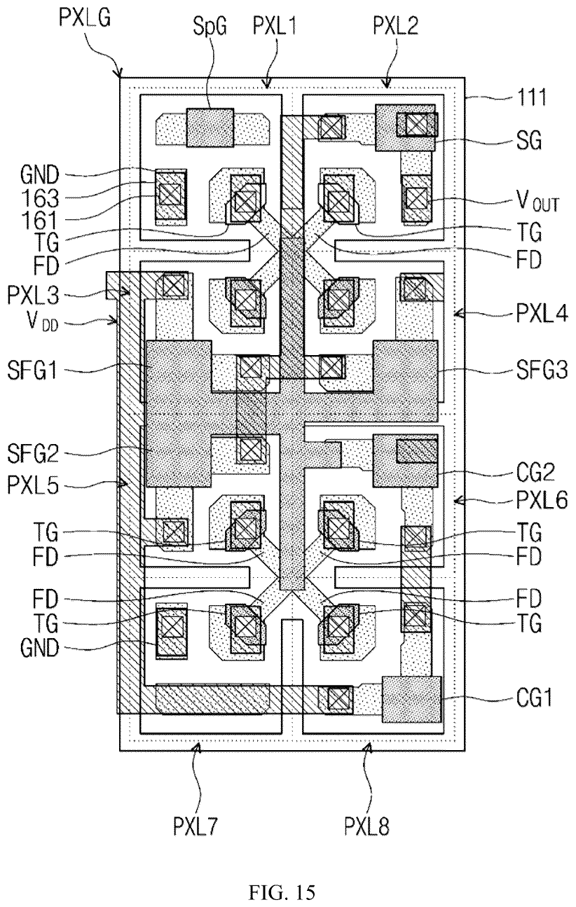

FIG. 13 is a plan view of the image sensor according to one embodiment of the disclosure. FIGS. 14 and 15 are plan views of the image sensors according to one embodiment of the disclosure.

Referring to FIGS. 13 to 15, the pixel group PXLG in FIGS. 13 to 15 may be composed of eight pixels PXL1 to PXL8 and may include eight transfer gates TG. The active areas in FIGS. 13 to 15 are provided in somewhat similar locations to the active areas in FIG. 12, but, in FIGS. 13 to 15, locations for some transistors may be different since the pixel group PXLG is composed of eight pixels PXL1 to PXL8.

For example, the first and seventh pixels PXL1 and PXL7 of FIGS. 13 to 15 may include the transfer gates TG, the ground areas GND, and spare gates SpG including the first active areas, the fifth active areas, and spare active areas, the second pixel PXL2 may include the transfer gate TG and the selection gate SG including the first active area and the fourth active area, the third to fifth pixels PXL3 to PXL5 may include the transfer gates TG and the source follower gates SFG1 to SFG3 including the first active areas and the third active areas, and the sixth and eighth pixels PXL6 and PXL8 may include the transfer gates TG, the first control gate CG1, and the second control gate CG2 including the first active areas and the second active areas.

Each of (or at least one of) the first active areas in FIGS. 13 to 15 may have a shape similar to the shape of the first active area in FIG. 12. For example, each of (or at least one of) the first active areas in FIGS. 13 to 15 may be disposed to be connected to the source follower gates SFG1 to SFG3 extending to the center portion of the pixel group PXLG when the pixel group PXLG is viewed from a plan view. In FIGS. 13 to 15, the plurality of first active areas may be provided to respectively correspond to the transfer gates TG.

In FIGS. 13 to 15, some of the first active areas may be disposed to be connected to the source follower gates SFG1 to SFG3 extending to a center portion of the first to fourth pixels PXL1 to PXL4 when the pixel group PXLG is viewed from a plan view, and other some of the first active areas may be disposed to be connected to the source follower gates SFG1 to SFG3 extending to a center portion of the fifth to eighth pixels PXL5 to PXL8. In this case, the first active areas of the first to fourth pixels PXL1 to PXL4 may be in direct contact with each other at the center portion of the first to fourth pixels PXL1 to PXL4 to form a single body, or may be spaced apart from each other while extending toward the center portion of the first to fourth pixels PXL1 to PXL4. Likewise, the first active areas of the fifth to eighth pixels PXL5 to PXL8 may be in direct contact with each other at the center portion of the fifth to eighth pixels PXL5 to PXL8 to form a single body, or may be spaced apart from each other while extending toward the center portion of the fifth to eighth pixels PXL5 to PXL8.

In FIGS. 13 to 15, the plurality of second active areas may be disposed in different pixels. For example, in FIGS. 13 to 15, the second active areas may include the second active area provided in the sixth pixel PXL6 and the second active area provided in the eighth pixel PXL8. In this case, the common source/drain area between the first control gate CG1 and the second control gate CG2 may also be divided into two common source/drain areas. The common source/drain areas spaced apart from each other may be electrically connected through the corresponding contact plugs and the corresponding wiring.

The second active area of the sixth pixel PXL6 according to one embodiment may be in direct contact with the source follower gates SFG1 to SFG3 extending along the deep element isolation pattern from the third active area. For example, the shallow element isolation pattern overlapped on the deep element isolation pattern of the pixel group PXLG may be in contact with the second active area of the sixth pixel PXL6, and the shallow element isolation pattern may include the recessed area defined by recessing a side of the shallow element isolation pattern being in contact with the second active area. In this case, the source follower gates SFG1 to SFG3 extending along the deep element isolation pattern may fill the recessed area. That is, the source follower gates SFG1 to SFG3 may cover the exposed shallow element isolation pattern by the recess.

In one embodiment, the gate insulating film may be provided between the source follower gates SFG1 to SFG3 and the shallow element isolation pattern and between the source follower gates SFG1 to SFG3 and the second active area, and the source follower gates SFG1 to SFG3 may pass through the gate insulating film to be in direct contact with the control source/drain area in the second active area.

In one embodiment, the gate insulating film may be removed between the source follower gates SFG1 to SFG3 and the shallow element isolation pattern, and between the source follower gates SFG1 to SFG3 and the second active area, and the source follower gates SFG1 to SFG3 may be in direct contact with the shallow element isolation pattern and the control source/drain area in the second active area.

The source follower gates SFG1 to SFG3 disposed on the third active area as described above may extend along the deep element isolation pattern from the third active area and may be in contact with the first and second active areas. When the source follower gates SFG1 to SFG3 are disposed above the deep element isolation pattern, the shallow element isolation pattern overlapped on the deep element isolation pattern corresponding to a location of the source follower gates SFG1 to SFG3 may be recessed to include the recessed area. That is, the shallow element isolation pattern may include the recessed area at a location corresponding to the source follower gates SFG1 to SFG3 and the deep element isolation pattern when viewed from a plan view, and the source follower gates SFG1 to SFG3 disposed at the location may fill the recessed area.

In one embodiment, the source follower gates SFG1 to SFG3 may be respectively disposed in the third to fifth pixels PXL3 to PXL5, and the first to third source follower gates SFG1 to SFG3 may be selectively used.

In one embodiment, FIG. 13 shows an embodiment selectively using the first source follower gate SFG1. For example, the first source follower gate SFG1 of FIG. 13 may extend along the deep element isolation pattern from the third active area of the third pixel PXL3 to be disposed at the central location of the first to fourth pixels PXL1 to PXL4 and the central location of the fifth to eighth pixels PXL5 to PXL8.

In one embodiment, FIG. 14 shows an embodiment selectively using the first and second source follower gates SFG1 and SFG2. For example, the first source follower gate SFG1 of FIG. 14 may extend along the deep element isolation pattern from the third active area of the third pixel PXL3, and the second source follower gate SFG2 of FIG. 14 may extend along the deep element isolation pattern from the third active area of the fifth pixel PXL5. In this case, the first and second source follower gates SFG1 and SFG2 of FIG. 14 may be in contact with each other to form an integrated source follower gate, and the integrated source follower gate may fill the recessed area of the shallow element isolation pattern overlapped on the deep element isolation pattern.

The integrated source follower gate disclosed in FIG. 14 may extend to be disposed in the center portion of the first to fourth pixels PXL1 to PXL4, and may also extend to be disposed in the center portion of the fifth to eighth pixels PXL5 to PXL8.

In one embodiment, FIG. 15 shows an embodiment selectively using the first to third source follower gates SFG1 to SFG3. For example, the first source follower gate SFG1 of FIG. 15 may extend along the deep element isolation pattern from the third active area of the third pixel PXL3, the second source follower gate SFG2 of FIG. 15 may extend along the deep element isolation pattern from the third active area of the fifth pixel PXL5, and the third source follower gate SFG3 may extend along the deep element isolation pattern from the third active area of the fourth pixel PXL4. The first to third source follower gates SFG1 to SFG3 may be in contact with each other to form an integrated source follower gate, and the integrated source follower gate may fill the recessed area included in the shallow element isolation pattern overlapped on the deep element isolation pattern.

The integrated source follower gate disclosed in FIG. 15 may extend to be disposed in the center portion of the first to fourth pixels PXL1 to PXL4, and may also extend and be located in the center portion of the fifth to eighth pixels PXL5 to PXL8.

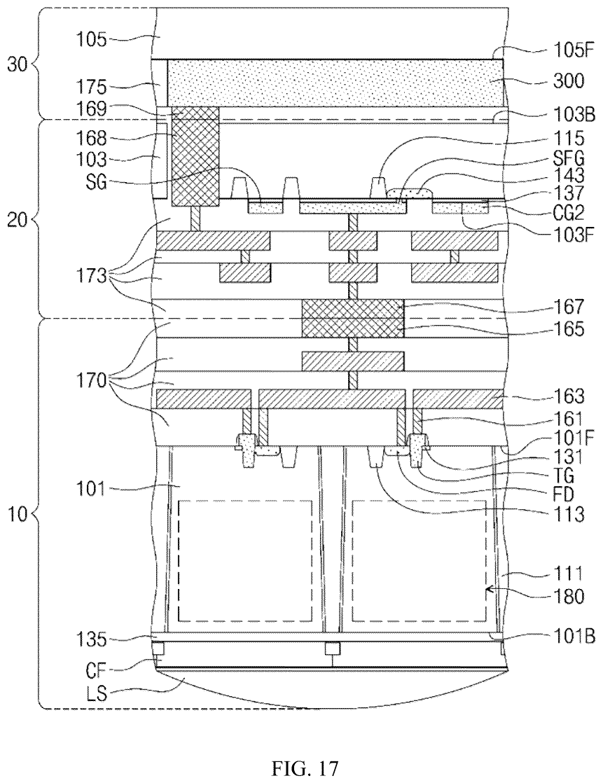

FIGS. 16 and 17 are cross-sectional views of the image sensor according to one embodiment of the disclosure. Referring to FIG. 16, the image sensor may include a photoelectric conversion structure 10 and a peripheral structure 30. The photoelectric conversion structure 10 may include the first substrate 101 that includes the plurality of photoelectric conversion areas 180, the deep element isolation pattern 111, the shallow element isolation pattern 113, the gate insulating film 131, a substrate insulating film 135 disposed on a second surface 101B of the first substrate 101, the contact plugs 161, the wiring 163, the bonding pads 165, the interlayer insulating film 170, microlenses LS disposed on the second surface 101B of the first substrate 101, and color filters CF between the first substrate 101 and the plurality of microlenses LS. The peripheral structure 30 may include a third substrate 105, a peripheral interlayer insulating film 175, and a logic circuit element 300.

The first substrate 101 may include the first surface 101F and the second surface 101B opposite to the first surface 101F, and the deep element isolation pattern 111 may pass through the first substrate 101 to define the pixel areas.

The shallow element isolation pattern 113 may be disposed in the first substrate 101 and may be adjacent to the first surface 101F of the first substrate 101. The shallow element isolation pattern 113 may define the active areas in the pixel areas. For example, the shallow element isolation pattern 113 may define first to fifth active areas in the pixel areas.

The gate insulating film 131 may be provided on the first surface 101F of the first substrate 101, and the gate insulating film 131 may be provided between the first substrate 101 and the gates TG and SFG. In some embodiments, other gates CG1, CG2, and SG described in the above embodiments may also be disposed on the first surface 101F of the first substrate 101.

The substrate insulating film 135 may be provided on the second surface 101B of the first substrate 101. The substrate insulating film 135 may cover the second surface 101B of the first substrate 101 and may have a single-layered or a multi-layered structure. For example, the substrate insulating film 135 may include a silicon-based insulating material (e.g., a silicon oxide, a silicon nitride, and/or a silicon oxynitride) and/or an insulating metal oxide.

The color filter CF may be provided on the substrate insulating film 135. In one embodiment, as shown, the color filter CF may be disposed on the second surface 101B of the first substrate 101 to correspond to each of (or at least one of) the pixels. In one embodiment, the color filter CF may be disposed to correspond to the plurality of pixels. Each of (or at least one of) the color filters CF may include one of a red (R) filter, a blue (B) filter, and a green (G) filter, but is not limited to thereto. In one embodiment, each of (or at least one of) the color filters CF may include one of other color filters such as a cyan (C) filter, a yellow (Y) filter, and a magenta (M) filter. For example, 4, 9, and/or 16 color filters CF may be provided in one pixel group.

The interlayer insulating film 170 may be provided on the first surface 101F of the first substrate 101. The interlayer insulating film 170 may cover the first surface 101F of the first substrate 101 and may have a single-layered or a multi-layered structure.

The microlens LS may be disposed on the second surface 101B of the first substrate 101. For example, the microlens LS may be disposed on the color filter CF. The microlens LS may include a lens pattern and a planarization portion. The planarization portion of the microlens LS may be provided on the color filters CF. The lens pattern may be provided on the planarization portion. The lens pattern may be integrally formed with the planarization portion and may be connected without an interface. The lens pattern may include the same material as the planarization portion. In one embodiment, the planarization portion may be omitted, and the lens pattern may be directly disposed on the color filter CF.

The lens pattern may be hemispherical. The lens pattern may concentrate incident light. The lens pattern may be provided at a location corresponding to the photoelectric conversion areas 180 of the first substrate 101. The microlens LS may be transparent to transmit light. The microlens LS may include an organic material such as polymer. For example, the microlens LS may include a photoresist material or a thermosetting resin.

The third substrate 105 may include a fifth surface 105F and a sixth surface opposite to the fifth surface 105F. The peripheral interlayer insulating film 175 may be provided on the fifth surface 105F of the third substrate 105. The peripheral interlayer insulating film 175 may cover the fifth surface 105F of the third substrate 105 and may have a single-layered or a multi-layered structure.

The logic circuit elements 300 may include at least some of the row decoder 2, the row driver 3, the column decoder 4, the timing generator 5, the correlated double sampler (CDS) 6, the analog-to-digital converter (ADC) 7, and the input/output buffer 8 of FIG. 1.

Referring to FIG. 17, the image sensor may include the photoelectric conversion structure 10, an intermediate structure 20, and the peripheral structure 30. In one embodiment, the photoelectric conversion structure 10 may include the first gate insulating film 131 and a first shallow element isolation pattern 113, the intermediate structure 20 may be provided between the photoelectric conversion structure 10 and the peripheral structure 30 and include the second substrate 103, a second shallow element isolation pattern 115, the gates TG, CG2, SFG, SG, the contact plugs 161, the wiring 163, the bonding pad 165, and the intermediate interlayer insulating film 173.

The first shallow element isolation pattern 113 may be provided in the first surface 101F of the first substrate 101. The first shallow element isolation pattern 113 may be formed adjacent to the first surface 101F of the first substrate 101 and may define the active areas in the pixel areas. For example, the first shallow element isolation pattern 113 may respectively define the first active areas in the pixel areas.

The second substrate 103 may include a third surface 103F and a fourth surface 103B opposite to the third surface 103F. The second shallow element isolation pattern 115 may be provided in the second substrate 103. The second shallow element isolation pattern 115 may be formed adjacent to the third surface 103F of the second substrate 103 and may define the active areas. For example, the second shallow element isolation pattern 115 may define the second to the fifth active areas.

The first gate insulating film 131 may be provided on the first surface 101F of the first substrate 101, and the first gate insulating film 131 may be provided between the first substrate 101 and the gates TG.

A second gate insulating film 137 may be provided on the third surface 103F of the second substrate 103, and the second gate insulating film 137 may be provided between the second substrate 103 and the gates SFG, CG2, and SG.

The intermediate interlayer insulating film 173 may be provided on the third surface 103F of the second substrate 103. The intermediate interlayer insulating film 173 may cover the third surface 103F of the second substrate 103 and may have a single-layered or a multi-layered structure.

In addition, referring to FIG. 16, the photoelectric conversion structure 10 and the peripheral structure 30 may be electrically connected by bonding pads 165 and 169. For example, the bonding pads 165 and 169 may electrically connect the plurality of wirings 163 and the logic circuit element 300. The interlayer insulating film 170 may surround a first bonding pad 165 in the photoelectric conversion structure 10, and the peripheral interlayer insulating film 175 may surround a third bonding pad 169 in the peripheral structure 30. For example, the interlayer insulating film 170 may expose a top surface of the first bonding pad 165 in the photoelectric conversion structure 10, and the peripheral interlayer insulating film 175 may expose a bottom surface of the third bonding pad 169 in the peripheral structure 30.

In addition, referring to FIG. 17, the photoelectric conversion structure 10 and the intermediate structure 20 may be electrically connected by bonding pads 165 and 167. For example, the bonding pads 165 and 167 may electrically connect the wirings 163 of the photoelectric conversion structure 10 to the wirings of the intermediate structure 20. The interlayer insulating film 170 of the photoelectric conversion structure 10 may expose the top surface of the first bonding pad 165 in the photoelectric conversion structure 10, the intermediate interlayer insulating film 173 in the intermediate structure 20 may expose a bottom surface of a second bonding pad 167, and a third bonding pad 168 in the intermediate structure 20 may pass through the second substrate 103. The peripheral interlayer insulating film 175 of the peripheral structure 30 may expose the bottom surface of the third bonding pad 169 in the peripheral structure 30.

In one embodiment, the first to fourth bonding pads 165, 167, 168, and 169 may include copper. The first and second bonding pads 165 and 167 may be bonded each other by a copper-copper bonding technique, and the third and fourth bonding pads 168 and 169 may be bonded each other by the copper-copper bonding technique. In one embodiment, the bonding pads 165 and 167, or 168 and 169 bonded each other may form a single body without an interface therebetween. In addition, bonded ones among the plurality of interlayer insulating films 170, 173, and 175 may be joined to form covalent bonds.

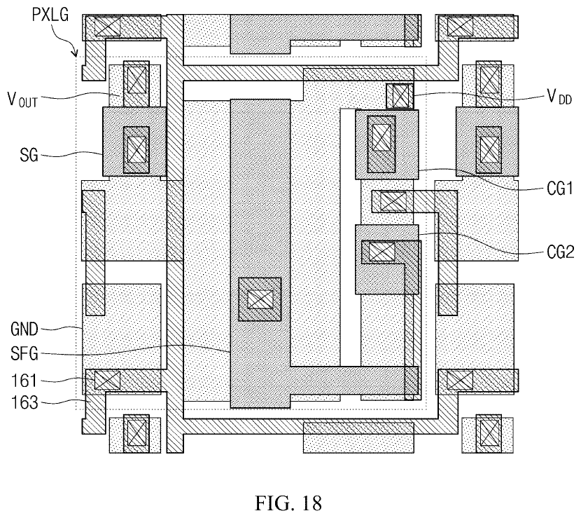

FIG. 18 is a plan view of the intermediate structure according to one embodiment of the disclosure. Referring to FIG. 18, the intermediate structure may include the second to fifth active areas in the pixel group PXLG, the first control gate CG1 of the first control transistor, the second control gate CG2 of the second control transistor, the source follower gate SFG, the selection gate SG, and the ground area GND. In one embodiment, since the photoelectric conversion areas and the transfer gate of the transfer transistor are disposed in the photoelectric conversion structure, a plan view of the intermediate structure is not disclosed.

The source follower gate SFG of FIG. 18 may extend from the third active area to the second active area via the second shallow element isolation pattern to be disposed on the control source/drain area. The second shallow element isolation pattern between the second active area and the third active area may be recessed to expose a side surface of the control source/drain area, and the source follower gate SFG may cover the exposed side surface of the control source/drain area.

In one embodiment, the gate insulating film may be disposed between the source follower gate SFG and the second and third active areas, and the source follower gate SFG may pass through the gate insulating film to be in direct contact with the second active area. In other words, the source follower gate SFG may pass through the gate insulating film to be in direct contact with the control source/drain area.

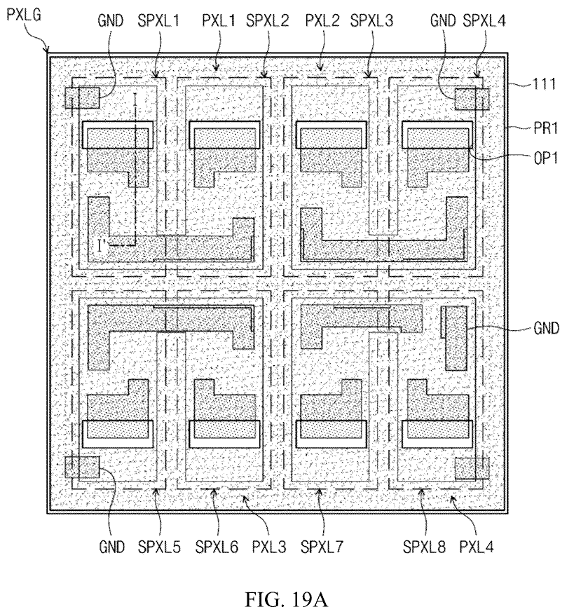

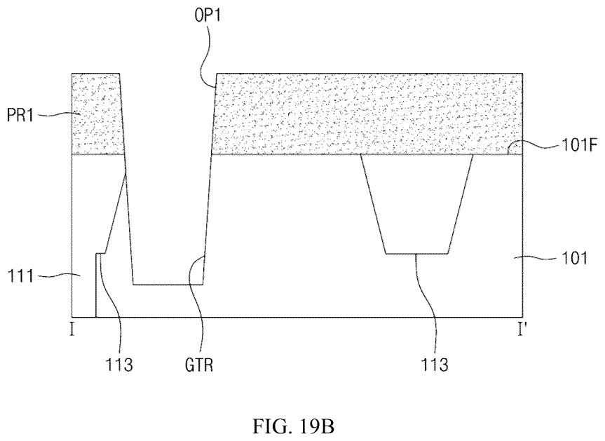

FIGS. 19A to 25C are cross-sectional views and plan views showing a manufacturing method for the image sensor according to one embodiment of the disclosure. FIG. 19A is a plan view, and FIG. 19B is a cross-sectional view corresponding to line I-I′ of FIG. 19A. Referring to FIGS. 19A and 19B, a first photoresist pattern PR1 having first openings OP1 may be formed on the substrate 101 having the deep element isolation pattern 111 and the shallow element isolation pattern 113. The substrate 101 may be recessed using the first photoresist pattern PR1 as an etching mask to form a plurality of gate trenches GTR in the substrate 101. The gate trenches GTR may be formed in a part of the first active area and the shallow element isolation pattern 113.

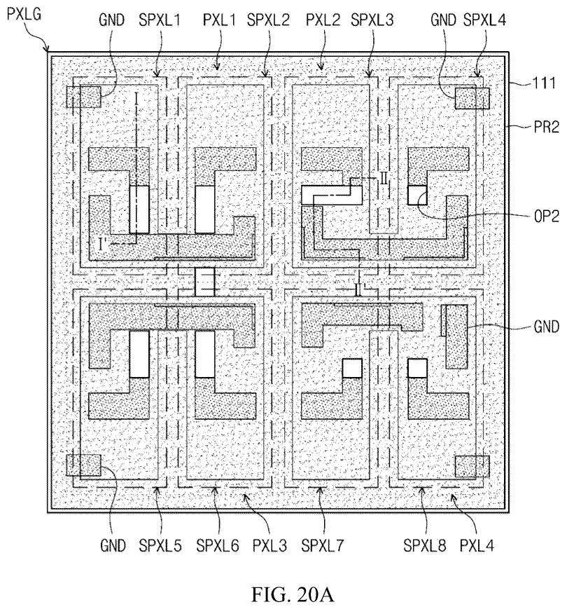

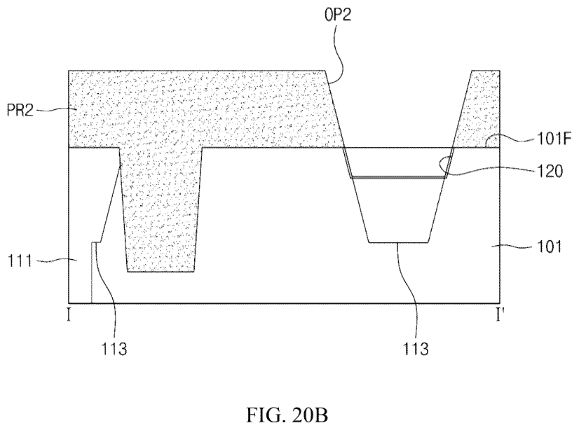

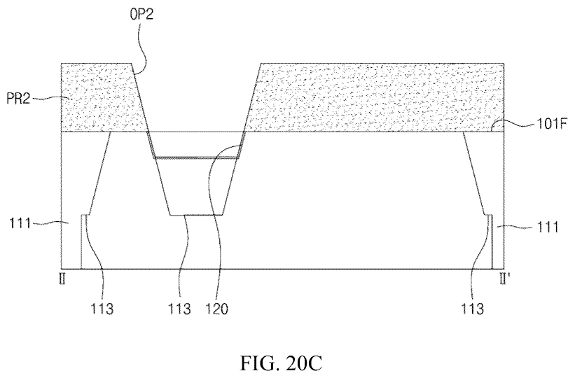

FIG. 20A is a plan view, FIG. 20B is a cross-sectional view corresponding to line I-I′ of FIG. 20A and FIG. 20C is a cross-sectional view corresponding to line II-II′ of FIG. 20A. Referring to FIGS. 20A to 20C, the first photoresist pattern PR1 may be removed, and a second photoresist pattern PR2 having second openings OP2 may be formed on the substrate 101. The second openings OP2 may expose portions of the shallow element isolation pattern 113. The shallow element isolation pattern 113 may be recessed using the second photoresist pattern PR2 as an etching mask to form the recessed areas 120. The shallow element isolation pattern 113 including the recessed areas 120 may be limited to the shallow element isolation pattern corresponding to a location of the source follower gate and being in contact with the floating diffusion region and/or the control source/drain area.

For example, the recessed areas 120 may be formed in the shallow element isolation pattern 113 between the first active area and the second active area, the shallow element isolation pattern 113 in contact with the first active area, the shallow element isolation pattern 113 in contact with the control source/drain area in the second active area, the shallow element isolation pattern 113 between the first active area and the control source/drain area, and the shallow element isolation pattern 113 between the third active areas. The shallow element isolation pattern including the recessed areas 120 according to one embodiment is shown in FIG. 20A.

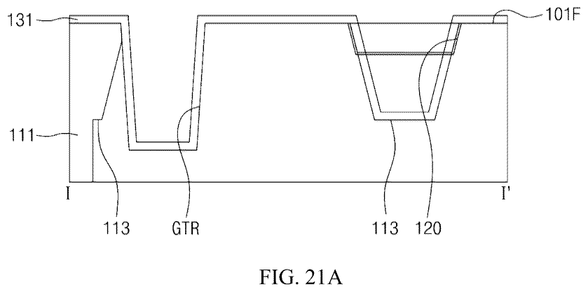

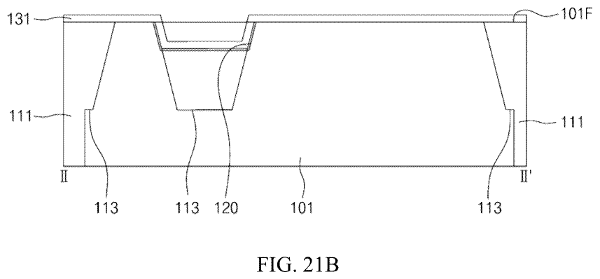

FIG. 21A is a cross-sectional view corresponding to line I-I′ of FIG. 20A and FIG. 21B is a cross-sectional view corresponding to line II-II′ of FIG. 20A. Referring to FIGS. 21A to 21B, the second photoresist pattern PR2 may be removed, and the gate insulating film 131 may be formed on the substrate 101. The gate insulating film 131 may be conformally formed on the first surface 101F of the substrate 101.

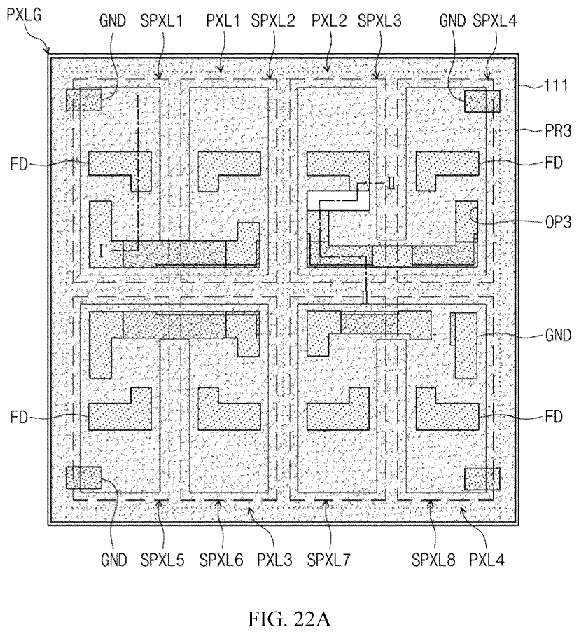

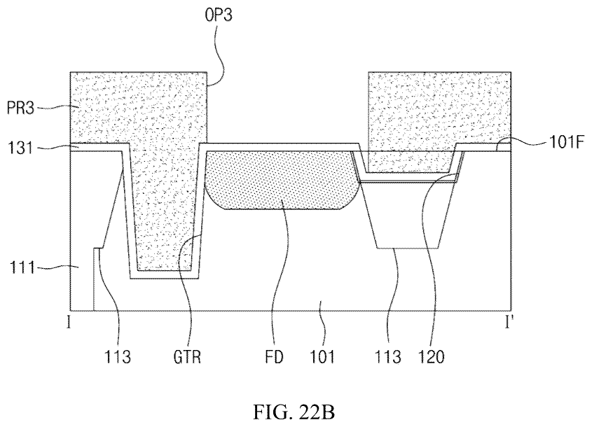

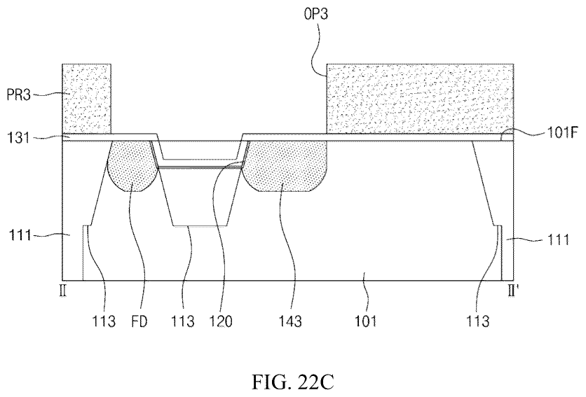

FIG. 22A is a plan view, FIG. 22B is a cross-sectional view corresponding to line I-I′ of FIG. 22A and FIG. 22C is a cross-sectional view corresponding to line II-II′ of FIG. 22A. Referring to FIGS. 22A to 22C, a third photoresist pattern PR having third openings OP3 may be formed on the substrate 101. Impurity ions may be injected into the active areas through the third openings OP3.

In one embodiment, through the ion injection process, the floating diffusion regions FD and the source/drain areas may be formed in the active areas. For example, the floating diffusion regions FD may be respectively formed in the first active areas, the control source/drain areas, the common source/drain areas, and the power source/drain areas may be formed in the second active area, and the source/drain areas may be formed in the third and fourth active areas.

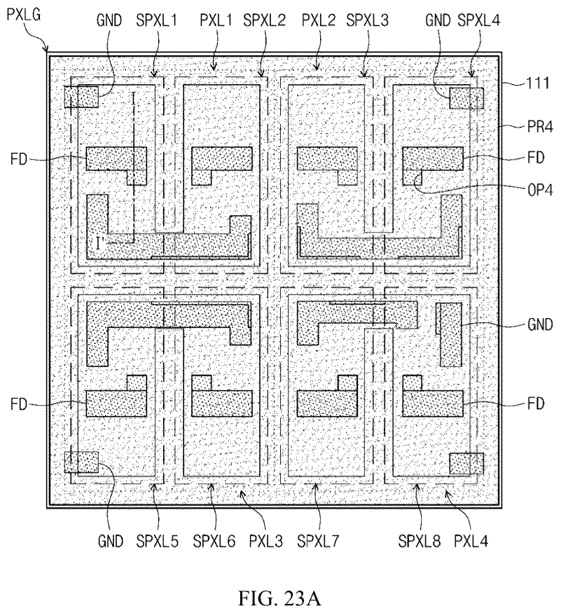

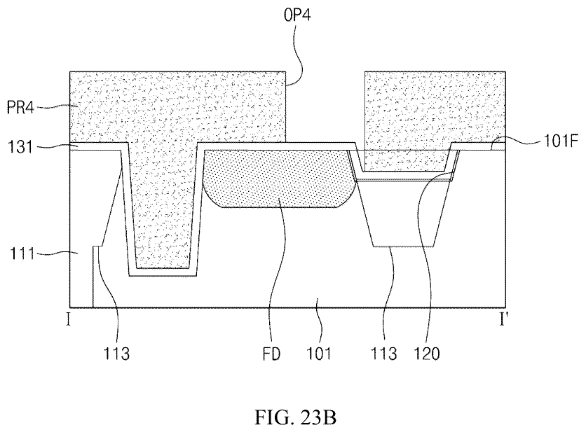

FIG. 23A is a plan view and FIG. 23B is a cross-sectional view corresponding to line I-I′ of FIG. 23A. Referring to FIGS. 23A and 23B, the third photoresist pattern PR3 may be removed, and a fourth photoresist pattern PR4 having fourth openings OP4 may be formed on the substrate 101. Impurity ions may be injected into the first active areas through the fourth openings OP4. An area into which the impurity ions are injected may be one portion of the floating diffusion region FD. In other words, an impurity concentration of the one portion of the floating diffusion region FD may be higher than an impurity concentration of other portion of the floating diffusion region FD. In one embodiment, the one portion of the floating diffusion region FD with higher impurity concentration may be in direct contact with the described source follower gate described below.

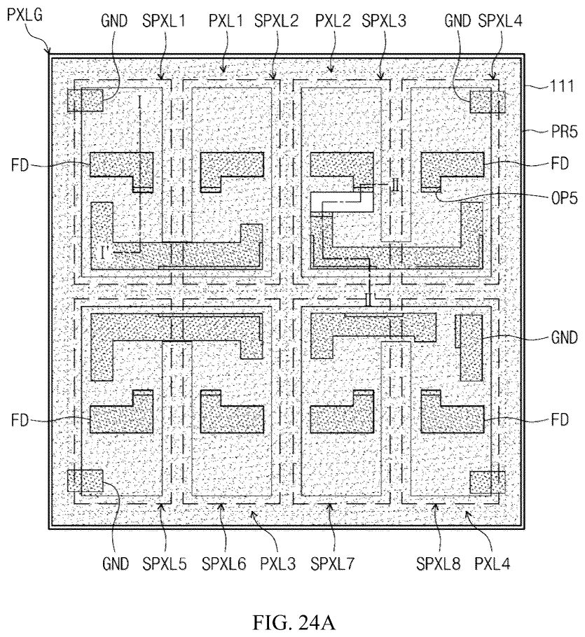

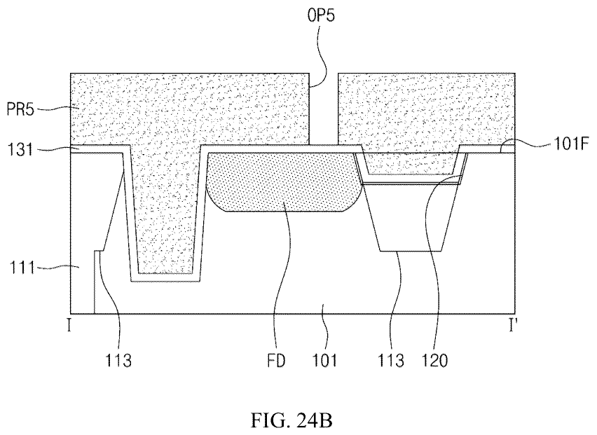

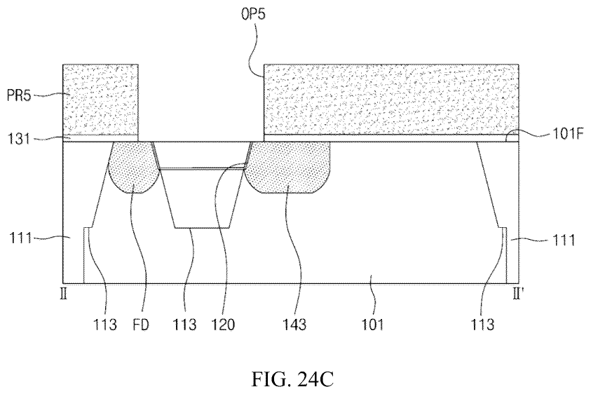

FIG. 24A is a plan view, FIG. 24B is a cross-sectional view corresponding to line I-I′ of FIG. 24A and FIG. 24C is a cross-sectional view corresponding to line II-II′ of FIG. 24A. Referring to FIGS. 24A to 24C, the fourth photoresist pattern PR4 may be removed, and a fifth photoresist pattern PR5 having fifth openings OP5 may be formed on the substrate 101. The fifth openings OP5 may expose portions of the gate insulating film 131. In one embodiment, the fifth openings OP5 may overlap at least one of one portion of the control source/drain area 143, the one portion of the floating diffusion region FD, and the recessed areas 120. The exposed portions of the gate insulating film 131 may be removed using the fifth photoresist pattern PR5 as an etch mask.

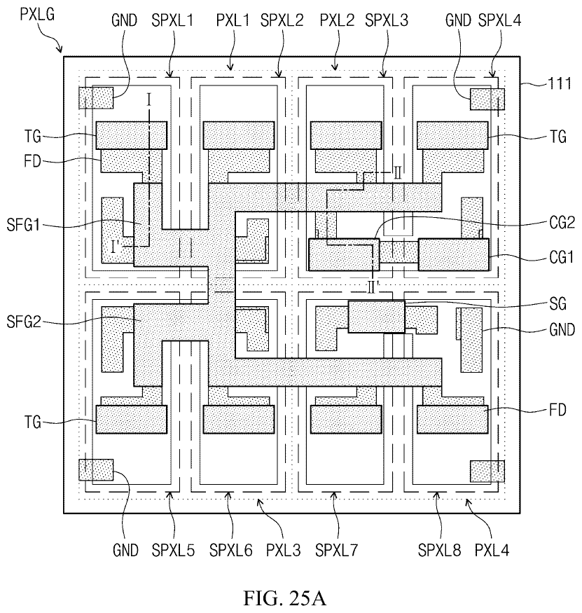

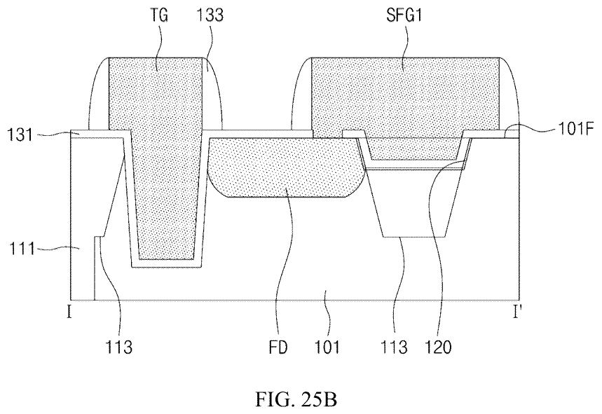

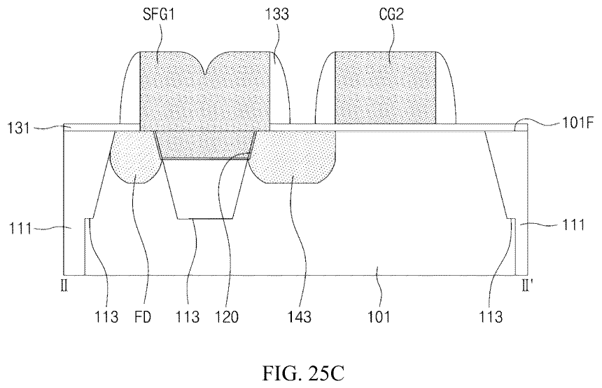

FIG. 25A is a plan view, FIG. 25B is a cross-sectional view corresponding to line I-I′ of FIG. 25A and FIG. 25C is a cross-sectional view corresponding to line II-II′ of FIG. 25A. Referring to FIGS. 25A to 25C, the fifth photoresist pattern PR5 may be removed. A conductive film may be formed on the first surface 101F of the substrate 101, and a patterning process may be performed on the conductive film to form gates.

In one embodiment, a gate spacer 133 may be formed on side surfaces of the gates. A gate spacer film may be conformally formed on the substrate 101 having the gates, and an anisotropic etching process may be performed on the gate spacer film to form the gate spacer 133.

As described above, according to the embodiments of the disclosure, the source follower gate may be in direct contact with the control source/drain area and may be in direct contact with the floating diffusion region. Thus, parasitic capacitance in the image sensor can be minimized. As a result, since a conversion gain of the pixel can be improved, performance of the image sensor can be enhanced.

Those skilled in the art or those having ordinary skill in the art will understand that various modifications and changes can be made to the disclosure without departing from the spirit and technical scope of the disclosure as set forth in the claims described below. For example, the above-described embodiments may be combined in various forms to the extent that they are not compatible with each other.

What is claimed is:

1. An image sensor comprising:
a substrate having a first surface and a second surface opposite to the first surface;
a deep element isolation pattern in the substrate to define a plurality of pixel areas;
a shallow element isolation pattern adjacent to the first surface to define a first active area, a second active area, and a third active area, wherein the first active area, the second active area, and the third active area are spaced apart in the plurality of pixel areas;
a floating diffusion region in the first active area;
a control source/drain area in the second active area;
a source follower gate on the third active area; and
a gate insulating film between the source follower gate and the third active area;
wherein the source follower gate and the gate insulating film extend to the control source/drain area, and
wherein the source follower gate passes through the gate insulating film and is in direct contact with the control source/drain area.

2. The image sensor of claim 1, wherein the source follower gate and the gate insulating film extend on the floating diffusion region, and
wherein the source follower gate passes through the gate insulating film and is in direct contact with the floating diffusion region.

3. The image sensor of claim 2, wherein the shallow element isolation pattern between the control source/drain area and the floating diffusion region is recessed to define a recessed area, and
wherein the source follower gate fills the recessed area.

4. The image sensor of claim 3, wherein the recessed area exposes one side surface of the control source/drain area and one side surface of the floating diffusion region, and
wherein the source follower gate is in direct contact with the exposed side surface of the control source/drain area and the exposed side surface of the floating diffusion region.

5. The image sensor of claim 2, wherein the shallow element isolation pattern between the floating diffusion region and the third active area is recessed to define a recessed area, and
wherein the source follower gate fills the recessed area.

6. The image sensor of claim 1, further comprising a first control gate disposed on the second active area of one side of the control source/drain area,
wherein the control source/drain area and the first control gate are form a reset transistor.

7. The image sensor of claim 1, further comprising: a first control gate on the second active area of one side of the control source/drain area;
a second control gate on the second active area between the control source/drain area and the first control gate; and
a common source/drain area in the second active area between the first control gate and the second control gate,
wherein the common source/drain area and the first control gate forms a reset transistor, and
wherein the control source/drain area, the second control gate, and the common source/drain area form a dual conversion gain transistor.

8. The image sensor of claim 1, further comprising:
a photoelectric conversion area in at least one of the plurality of pixel areas; and
a transfer gate on the first active area,
wherein the gate insulating film is between the transfer gate and the first active area.

9. The image sensor of claim 1, wherein the shallow element isolation pattern at both sides of the third active area is recessed to expose both side surfaces of the third active area, and
wherein the source follower gate and the gate insulating film are on the exposed both side surfaces of the third active area.

10. The image sensor of claim 1, wherein the first active area, the second active area, and the third active area are defined in at least one of the plurality of pixel areas.

11. The image sensor of claim 1, wherein at least two of the plurality of pixel areas form a pixel group,
wherein the plurality of pixel areas comprise a plurality of pixel groups,
wherein the first active area is defined in at least one of the plurality of pixel areas, and
wherein the second active area and the third active area are defined in at least one of the plurality of pixel groups.

12. The image sensor of claim 11, wherein at least one of the plurality of pixel groups comprises a plurality of third active areas and a plurality of source follower gates respectively disposed on the plurality of third active areas, and
wherein at least one of the plurality of source follower gates of the plurality of pixel groups forms an integrated source follower gate connected with each other.

13. The image sensor of claim 1, wherein at least one of the plurality of pixel areas comprises a plurality of sub-pixel areas, and
wherein the first active area is defined in at least one of the plurality of sub-pixel areas.

14. An image sensor comprising:
a substrate having a first surface and a second surface opposite to the first surface;
a deep element isolation pattern in the substrate to define a plurality of pixel areas including a plurality of pixel groups;
a shallow element isolation pattern adjacent to the first surface to define first active areas, a second active area, and a third active area, wherein the first active areas, the second active area, and the third active area are respectively spaced apart in at least one of the plurality of pixel groups;
a photoelectric conversion area in at least one of the plurality of pixel areas;
a floating diffusion region in at least one of the first active areas;
a control source/drain area in the second active area;
a source follower gate on the third active area;
a gate insulating film between the source follower gate and the third active area; and
a color filter and a microlens sequentially stacked on the second surface of the substrate,
wherein the first active areas are respectively provided in at least one of the plurality of pixel areas of the plurality of pixel groups,
wherein the source follower gate and the gate insulating film extend on the control source/drain area, and
wherein the source follower gate passes through the gate insulating film and is in direct contact with the control source/drain area.

15. The image sensor of claim 14, wherein the source follower gate and the gate insulating film extend on the floating diffusion region, and
wherein the source follower gate passes through the gate insulating film and is in direct contact with the floating diffusion region.

16. The image sensor of claim 15, wherein the shallow element isolation pattern between one of the floating diffusion region and the control source/drain area is recessed to define a recessed area, and
wherein the source follower gate fills the recessed area.

17. The image sensor of claim 14, further comprising:
a first control gate on the second active area of one side of the control source/drain area;
a second control gate on the second active area between the control source/drain area and the first control gate; and
a common source/drain area in the second active area between the first control gate and the second control gate.

18. An image sensor comprising:
a first substrate having a first surface and a second surface opposite to the first surface;
a deep element isolation pattern in the first substrate to define pixel areas;
a first shallow element isolation pattern adjacent to the first surface of the first substrate to respectively define first active areas in the pixel areas;
a photoelectric conversion area in at least one of the pixel areas;
an interlayer insulating film on the first surface of the first substrate;
a second substrate disposed on the interlayer insulating film, wherein the second substrate has a third surface facing the first surface of the first substrate and a fourth surface opposite to the third surface;
a second shallow element isolation pattern adjacent to the third surface of the second substrate to define a second active area and a third active area;
a floating diffusion region respectively in the first active areas;
a control source/drain area in the second active area;
a source follower gate disposed on the third surface of the second substrate, wherein the source follower gate crosses the third active area; and
a gate insulating film disposed between the third active area and the source follower gate,
wherein the source follower gate and the gate insulating film extend on the control source/drain area, and
wherein the source follower gate passes through the gate insulating film and is in direct contact with the control source/drain area.

19. The image sensor of claim 18, wherein the second shallow element isolation pattern adjacent to the control source/drain area is recessed to define a recessed area, and
wherein the source follower gate fills the recessed area.

20. The image sensor of claim 18, further comprising:
an intermediate interlayer insulating film disposed on the third surface of the second substrate and covering the source follower gate;
a first bonding pad in an upper portion of the interlayer insulating film; and
a second bonding pad in a lower portion of the intermediate interlayer insulating film,
wherein the first bonding pad is bonded to the second bonding pad, and
wherein at least one of the floating diffusion regions is electrically connected to the source follower gate through the bonded first bonding pad and the bonded second bonding pad.
